(19) United States
(12) Patent Application Publication
(10) Pub. No.: US 2024/0258264 A1
(43) Pub. Date: Aug. 1, 2024

(54) SEMICONDUCTOR DEVICE AND METHOD FOR MANUFACTURING THE SAME

(71) Applicant: DENSO CORPORATION, Kariya-city (JP)

(72) Inventors: Takanori KAWASHIMA, Kariya-city (JP); Shinji HIRAMITSU, Kariya-city (JP); Tomomi OKUMURA, Kariya-city (JP)

(21) Appl. No.: 18/597,486

(22) Filed: Mar. 6, 2024

Related U.S. Application Data
(63) Continuation of application No. PCT/JP2022/032094, filed on Aug. 25, 2022.

(30) Foreign Application Priority Data
Sep. 21, 2021 (JP) 2021-153458

(51) Int. Cl. H01L 23/00; H01L 23/498; H01L 25/00; H01L 25/07

(52) U.S. Cl. CPC H01L 24/48; H01L 23/49811; H01L 23/49844; H01L 24/73; H01L 25/072; H01L 25/50; H01L 24/32; H01L 2224/32225; H01L 2224/48175; H01L 2224/73265; H01L 2924/1815

(57) ABSTRACT

A semiconductor device includes a semiconductor element, a first wiring member electrically connected to a first main electrode on a first surface of the semiconductor element, a second wiring member electrically connected to a second main electrode on a second surface of the semiconductor element, a signal terminal connected to a signal pad on the second surface through a bonding wire. The second wiring member includes an insulating base material, a front surface metal body on a front surface of the insulating base material adjacent to the semiconductor element, and a back surface metal body on a back surface. An end portion of the front surface metal body is located between an end portion of a bonding target to which the front surface metal body is bonded and an end portion of the semiconductor element in an arrangement direction of the semiconductor element and the signal terminal.

### CROSS REFERENCE TO RELATED APPLICATIONS

The present application is a continuation application of International Patent Application No. PCT/JP2022/032094 filed on Aug. 25, 2022, which designated the U.S. and claims the benefit of priority from Japanese Patent Application No. 2021-153458 filed on Sep. 21, 2021. The entire disclosures of all of the above applications are incorporated herein by reference.

### TECHNICAL FIELD

The present disclosure relates to a semiconductor device and a method for manufacturing the same.

### BACKGROUND

For example, JP 2020-64907 A discloses a semiconductor device that includes a semiconductor chip having main electrodes on opposite surfaces thereof, a first heat sink, a second heat sink, and a signal terminal. A drain electrode is provided on one surface of the semiconductor chip, and a source electrode and a signal pad are provided on a back surface of the semiconductor chip. The first heat sink is electrically connected to the drain electrode, and the second heat sink is electrically connected to the source electrode. The signal terminal is connected to the signal pad via a bonding wire. The disclosure of JP 2020-64907 A is incorporated herein by reference as an explanation of technical elements in the present disclosure.

### SUMMARY

The present disclosure describes a semiconductor device and a method for manufacturing the semiconductor device. A semiconductor device according to an aspect includes a semiconductor element, a first wiring member electrically connected to a first main electrode on a first surface of the semiconductor element, a second wiring member electrically connected to a second main electrode on a second surface of the semiconductor element, a signal terminal connected to a signal pad on the second surface through a bonding wire. The second wiring member includes an insulating base material, a front surface metal body on a front surface of the insulating base material adjacent to the semiconductor element, and a back surface metal body on a back surface of the insulating base material. An end portion of the front surface metal body is located between an end portion of a bonding target to which the front surface metal body is bonded and an end portion of the semiconductor element in an arrangement direction of the semiconductor element and the signal terminal.

### BRIEF DESCRIPTION OF THE DRAWINGS

FIG. 1 is a diagram illustrating a circuit configuration and a drive system of a power conversion device to which a semiconductor device is applied.

FIG. 2 is a perspective view of a semiconductor device according to the first embodiment.

FIG. 3 is a plan view when viewed along a direction Z1 in FIG. 2.

FIG. 4 is a cross-sectional view of the semiconductor device taken along a line IV-IV in FIG. 3.

FIG. 5 is a cross-sectional view of the semiconductor device taken along a line V-V in FIG. 3.

FIG. 6 is a cross-sectional view of the semiconductor device taken along a line VI-VI in FIG. 3.

FIG. 7 is a cross-sectional view of the semiconductor device taken along a line VII-VII in FIG. 3.

FIG. 8 is a plan view of a substrate on which a semiconductor element is mounted.

FIG. 9 is a plan view of a circuit pattern of the substrate on a drain electrode side.

FIG. 10 is a plan view of a circuit pattern of the substrate on a source electrode side.

FIG. 11 is an enlarged view of a region XI in FIG. 6.

FIG. 12 is a cross-sectional of a modified example.

FIG. 13 is a cross-sectional of a modified example.

FIG. 14 is a plan view of a modified example.

FIG. 15 is a plan view of a modified example.

FIG. 16 is a cross-sectional view of an example of a semiconductor device according to a second embodiment.

FIG. 17 is a cross-sectional view for showing a manufacturing process.

FIG. 18 is a diagram showing an effect of inductance reduction.

FIG. 19 is a cross-sectional view of another example of the semiconductor device.

FIG. 20 is a cross-sectional view of a modified example.

FIG. 21 is a perspective view of a semiconductor device according to a third embodiment.

FIG. 22 is a plan view of the semiconductor device when viewed along a direction Z2 in FIG. 21.

FIG. 23 is a cross-sectional view of the semiconductor device taken along a line XXIII-XXIII in FIG. 22.

FIG. 24 is a cross-sectional view of the semiconductor device taken along a line XXIV-XXIV in FIG. 22.

### DETAILED DESCRIPTION

In a semiconductor device having a double-sided heat dissipation structure, which is for example represented by JP2020-64907 A, a terminal (conductive spacer) may be disposed between a source electrode and a second heat sink in order to avoid contact between a bonding wire and the second heat sink, that is, in order to secure the height of the bonding wire. The thicker the terminal is, the farther the facing surfaces of a first heat sink and the second heat sink are away from each other, and the effect of magnetic flux cancellation by the currents flowing in opposite directions, that is, the effect of inductance reduction is likely to be reduced. It may also increase thermal resistance.

In addition, it is conceivable that a portion of the second heat sink closer to the signal terminal than the terminal is cut out to avoid contact between the bonding wire and the second heat sink and to bring the facing surfaces of the first heat sink and the second heat sink close to each other. However, heat diffusion from the semiconductor element to the second heat sink is inhibited by the cutout. In such a configuration, it is difficult to reduce the dead space. From the above-described viewpoint or from other viewpoints not mentioned, further improvement is required for the semiconductor device.

The present disclosure provides a semiconductor device capable of reducing thermal resistance while reducing inductance, and a method for manufacturing the semiconductor device.

According to an aspect of the present disclosure, a semiconductor device includes: a semiconductor element having a first surface and a second surface opposite to the first surface in a thickness direction, and including a first main electrode disposed on the first surface, a second main electrode disposed on the second surface, and a signal pad disposed at a position different from the second main electrode on the second surface; a first wiring member electrically connected to the first main electrode; a second wiring member electrically connected to the second main electrode; a signal terminal; and a bonding wire electrically connecting the signal pad and the signal terminal. In the semiconductor device, the second wiring member is a substrate having an insulating base material, a front surface metal body, and a back surface metal body. The front surface metal body is disposed on a front surface of the insulating base material adjacent to the semiconductor element and is electrically connected to the second main electrode. The back surface metal body is disposed on a back surface of the insulating base material. An end portion of the front surface metal body is located between an end portion of a bonding target to which the front surface metal body is bonded and an end portion of the semiconductor element in an arrangement direction of the semiconductor element and the signal terminal.

In such a semiconductor device, the substrate is used as the second wiring member. By patterning the front surface metal body of the substrate, the end portion of the front surface metal body is located between the end portion of the bonding target and the end portion of the semiconductor element in the arrangement direction. Since the end portion of the front surface metal body is located more to inside than the end portion of the semiconductor element in this manner, it is possible to avoid contact between the front surface metal body and the bonding wire and to bring the facing surfaces of the front surface metal body of the second wiring member and a conductive portion of the first wiring member close to each other. As a result, the effect of magnetic flux cancellation is enhanced, and inductance can be reduced. In addition, since the heat transfer path from the semiconductor element to the front surface metal body of the second wiring member is shortened, the thermal resistance can be reduced.

Further, since the end portion of the front surface metal body is located more to outside than the end portion of the bonding target, the heat of the semiconductor element can be diffused outside the bonding target through the front surface metal body. As such, the thermal resistance can be reduced. As a result, it is possible to reduce the thermal resistance while reducing the inductance.

According to an aspect of the present disclosure, a method for manufacturing a semiconductor device includes: electrically connecting a first main electrode disposed on a first surface of a semiconductor element and a first wiring member to each other; connecting a signal pad that is disposed on a second surface of the semiconductor element opposite to the first surface in a thickness direction to a signal terminal through a bonding wire; and, after the connecting of the signal pad and the signal terminal through the bonding wire, electrically connecting a second main electrode disposed at a position different from the signal pad on the second surface of the semiconductor element and a second wiring member to each other. In the electrically connecting of the second main electrode and the second wiring member, a substrate having an insulating base material, a front surface metal body and a back surface metal body is used. In the substrate, the front surface metal body is disposed on a front surface of the insulating base material adjacent to the semiconductor element, and electrically connected to the second main electrode; the back surface metal body is disposed on a back surface of the insulating base material; and the front surface metal body is patterned such that an end portion of the front surface metal body is located between an end portion of a bonding target to which the front surface metal body is bonded and an end portion of the semiconductor element in an arrangement direction of the semiconductor element and the signal terminal. In the electrically connecting of the second main electrode and the second wiring member, the second main electrode and the second wiring member are electrically connected to each other while an exposed portion of the insulating base material exposed from the front surface metal body is brought into contact with the bonding wire.

In such a method, the substrate is used as the second wiring member. The front surface metal body of the substrate is patterned such that the end portion of the front surface metal body is located between the end portion of the bonding target and the end portion of the semiconductor element in the arrangement direction. Since the end portion of the front surface metal body is located more to inside than the end portion of the semiconductor element, contact between the front surface metal body and the bonding wire can be avoided. Also, the facing surfaces of the front surface metal body of the second wiring member and a conductive portion of the first wiring member can be brought close to each other. As a result, the effect of magnetic flux cancellation is enhanced, and the inductance can be reduced. In addition, since the heat transfer path from the semiconductor element to the front surface metal body of the second wiring member is shortened, the thermal resistance can be reduced. By electrically connecting the second main electrode and the second wiring member in a state where the exposed portion of the insulating base material exposed from the front surface metal body is in contact with the bonding wire, the facing surfaces are brought closer to each other, and the effects of reducing the inductance and reducing the thermal resistance can be enhanced.

Further, since the end portion of the front surface metal body is located more to outside than the end portion of the bonding target, the heat of the semiconductor element can be diffused outside the end portion of the bonding target through the front surface metal body. As such, the thermal resistance can be reduced. As a result, it is possible to reduce the thermal resistance while reducing the inductance.

The disclosed aspects in this specification adopt different technical solutions from each other in order to achieve their respective objectives. Objects, features, and advantages disclosed in this specification will become apparent by referring to the following detailed descriptions and accompanying drawings.

Hereinafter, embodiments of the present disclosure will be described with reference to the drawings. The same or corresponding elements are designated with the same reference numerals throughout the embodiments, and descriptions thereof will not be repeated. When only part of the configurations is described in each embodiment, the configurations of the other preceding embodiments can be applied to the other parts of the configurations. A combination of configurations is not limited to the combination of the configurations explicitly described in the description of each embodiment. Configurations of a plurality of embodiments can be combined in part even if not explicitly described as long as there is no problem in the combination.

A semiconductor device of the present embodiment is applicable to, for example, a power conversion device of a movable object having a rotary electric machine as a drive source. The movable object is, for example, an electric vehicle such as an electrical vehicle (EV), a hybrid vehicle (HV), or a plug-in hybrid vehicle (PHV), a flying object such as a drone, a ship, a construction machine, or an agricultural machine. Hereinafter, an example in which the semiconductor device is applied to a vehicle will be described.

### First Embodiment

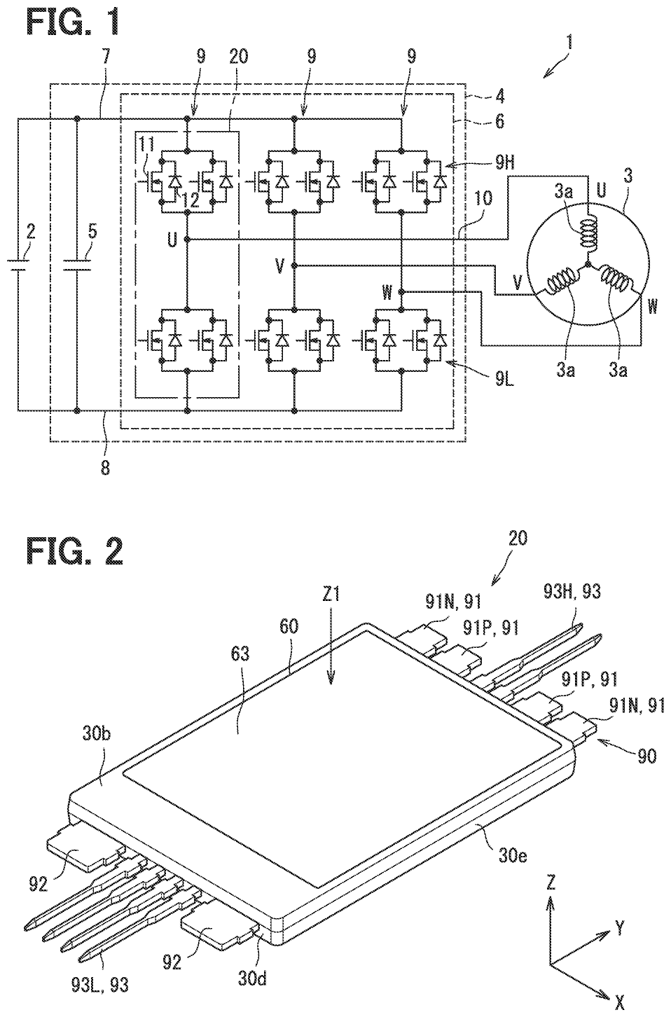

First, a schematic configuration of a drive system of a vehicle will be described with reference to FIG. 1.

### <Vehicle Drive System>

As shown in FIG. 1, a vehicle drive system 1 is provided with a direct current (DC) power supply 2, a motor generator 3, and an electric power conversion device 4.

The DC power supply 2 is a direct-current voltage source including a chargeable/dischargeable secondary battery. Examples of the secondary battery include a lithium ion battery and a nickel hydride battery. The motor generator 3 is a three-phase alternating current (AC) type rotary electric machine. The motor generator 3 functions as a drive source for traveling the vehicle, that is, an electric motor. The motor generator 3 functions as a generator during regeneration. The electric power conversion device 4 performs electric power conversion between the DC power supply 2 and the motor generator 3.

### <Electric Power Conversion Device>

Next, a circuit configuration of the electric power conversion device 4 will be described with reference to FIG. 1. The electric power conversion device 4 includes a power conversion circuit. The electric power conversion device 4 of the present embodiment includes a smoothing capacitor 5 and an inverter 6 that is a power conversion circuit.

The smoothing capacitor 5 mainly smoothes the DC voltage supplied from the DC power supply 2. The smoothing capacitor 5 is connected to a P line 7 which is a power supply line on a high potential side and an N line 8 which is a power supply line on a low potential side. The P line 7 is connected to a positive electrode of the DC power supply 2, and the N line 8 is connected to a negative electrode of the DC power supply 2. The positive electrode of the smoothing capacitor 5 is connected to the P line 7 between the DC power supply 2 and the inverter 6. The negative electrode of the smoothing capacitor 5 is connected to the N line 8 between the DC power supply 2 and the inverter 6. The smoothing capacitor 5 is connected to the DC power supply 2 in parallel. The P line 7 and the N line 8 may be referred to as power supply lines 7 and 8.

The inverter 6 corresponds to a DC-AC converter circuit. The inverter 6 converts the DC voltage into a three-phase AC voltage according to the switching control by a control circuit (not shown) and outputs the three-phase AC voltage to the motor generator 3. Thereby, the motor generator 3 is driven to generate a predetermined torque. At the time of regenerative braking of the vehicle, the inverter 6 converts the three-phase AC voltage generated by the motor generator 3 by receiving the rotational force from wheels into a DC voltage according to the switching control by the control circuit, and outputs the DC voltage to the P line. In this way, the inverter 6 performs bidirectional power conversion between the DC power supply 2 and the motor generator 3.

The inverter 6 includes upper-lower arm circuits 9 for three phases. The upper-lower arm circuit 9 may be referred to as a leg. The upper-lower arm circuit 9 includes an upper arm 9H and a lower arm 9L. The upper arm 9H and the lower arm 9L are connected in series between the P line 7 and the N line 8, and the upper arm 9H is adjacent to the P line 7. A connection point between the upper arm 9H and the lower arm 9L is connected to a winding 3a of a corresponding phase of the motor generator 3 via an output line 10. The inverter 6 has six arms. Each arm is configured to include a switching element. At least a part of each of the P line 7, the N line 8, and the output line 10 is configured by a conductive member such as a bus bar.

In the present embodiment, a switching element constituting each arm is provided by an n-channel MOSFET 11. The number of switching elements constituting each arm is not particularly limited. The number thereof may be one or more. The MOSFET is an abbreviation of a metal oxide semiconductor field effect transistor.

In the present embodiment, each arm has two MOSFETs 11, as an example. The two MOSFETs 11 constituting one arm are connected in parallel. In the upper arm 9H, the drains of the two MOSFETs 11 connected in parallel are connected to the P line 7. In the lower arm 9L, the sources of the two MOSFETs 11 connected in parallel are connected to the N line 8. The sources of the two MOSFETs 11 connected in parallel in the upper arm 9H and the drains of the two MOSFETs 11 connected in parallel in the lower arm 9L are connected to each other. The two MOSFETs 11 connected in parallel are turned on and off at the same timing by a common gate drive signal (drive voltage).

A freewheeling diode 12 is connected in antiparallel to each of the MOSFETs 11. The diode 12 may be a parasitic diode (body diode) of the MOSFET 11 or may be a diode provided separately from the parasitic diode. The anode of the diode 12 is connected to the source of the corresponding MOSFET 11, and the cathode of the diode 12 is connected to the drain of the corresponding MOSFET 11. The upper-lower arm circuit 9 for one phase is provided by one semiconductor device 20. Details of the semiconductor device 20 will be described later.

The electric power conversion device 4 may further include a converter as a power conversion circuit. The converter is a DC-DC converter circuit for converting the DC voltage to a DC voltage with different value. The converter is disposed between the DC power supply 2 and the smoothing capacitor 5. The converter includes, for example, a reactor and the upper-lower arm circuit 9 described above. The converter having such a configuration can boost and suppress the voltage. The electric power conversion device 4 may further include a filter capacitor for removing power supply noise from the DC power supply 2. The filter capacitor is provided between the DC power supply 2 and the converter.

The electric power conversion device 4 may include a drive circuit for the switching elements constituting the inverter 6 or the like. The drive circuit supplies a drive voltage to the gate of the MOSFET 11 of the corresponding arm based on the drive command of the control circuit. The drive circuit drives the corresponding MOSFET 11, that is, turns on and off the corresponding MOSFET 11 by applying the drive voltage. The drive circuit may be referred to as a driver.

The electric power conversion device 4 may include a control circuit for the switching element. The control circuit generates a drive command for operating the MOSFET 11 and outputs the drive command to the drive circuit. The control circuit generates the drive command based on, for example, a torque request input from a host ECU (not shown) or signals detected by various sensors. ECU is an abbreviation of an electronic control unit.

Examples of the various sensors include a current sensor, a rotation angle sensor, and a voltage sensor. The current sensor detects the phase current flowing through the winding 3a of each phase. The rotation angle sensor detects the rotation angle of the rotor of the motor generator 3. The voltage sensor detects the voltage across the smoothing capacitor 5. The control circuit includes, for example, a processor and a memory. The control circuit outputs, for example, a PWM signal as the drive command. PWM is an abbreviation of pulse width modulation.

### <Semiconductor Device>

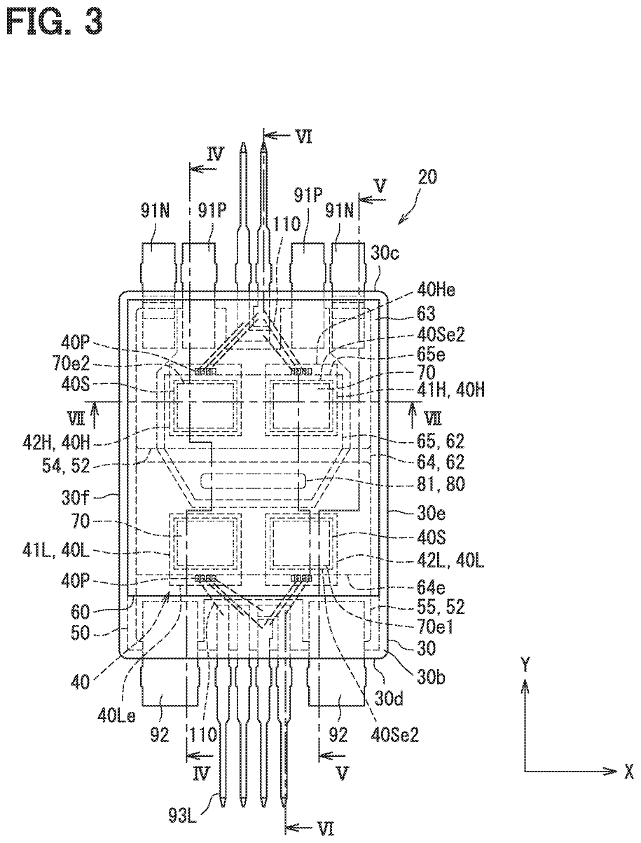

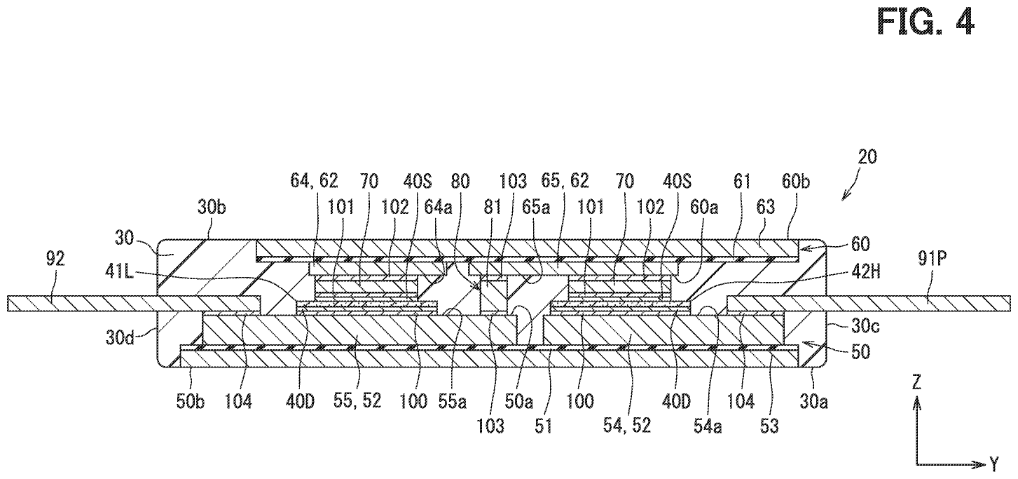

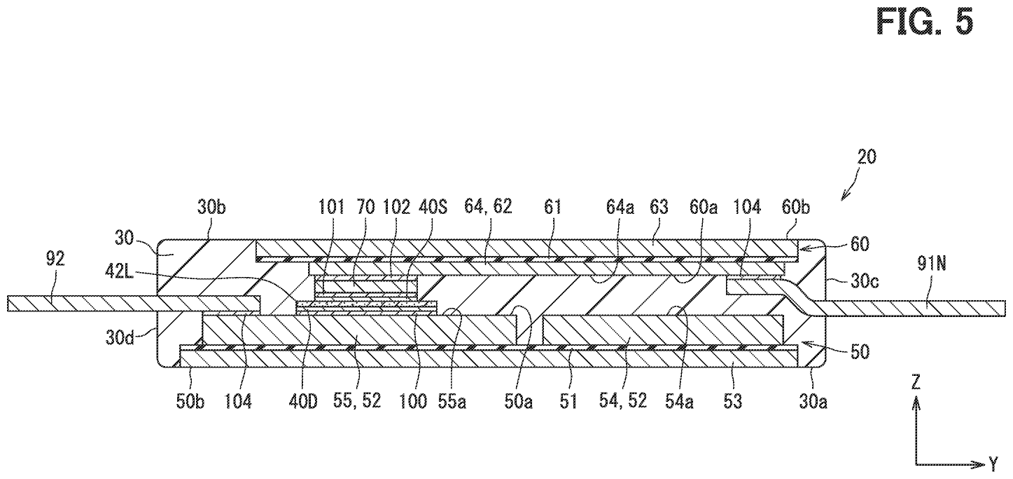

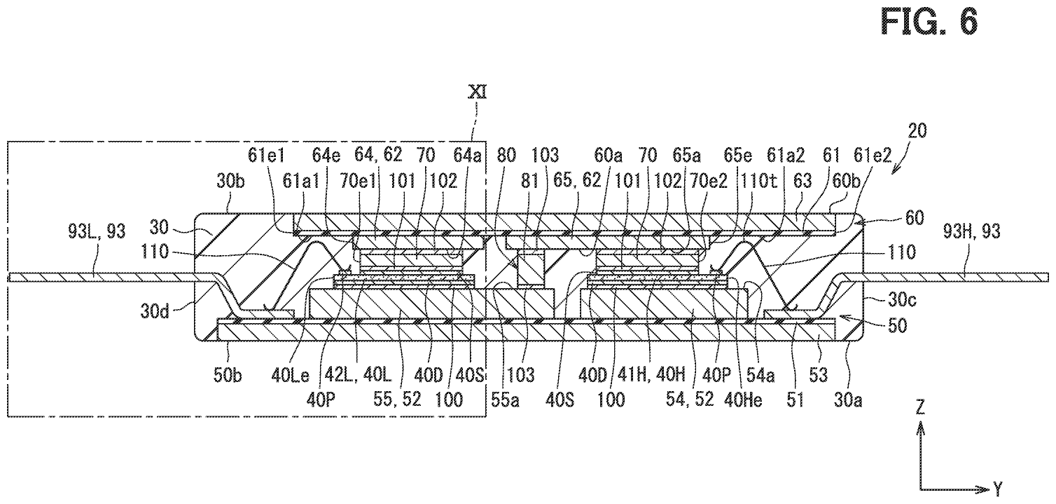

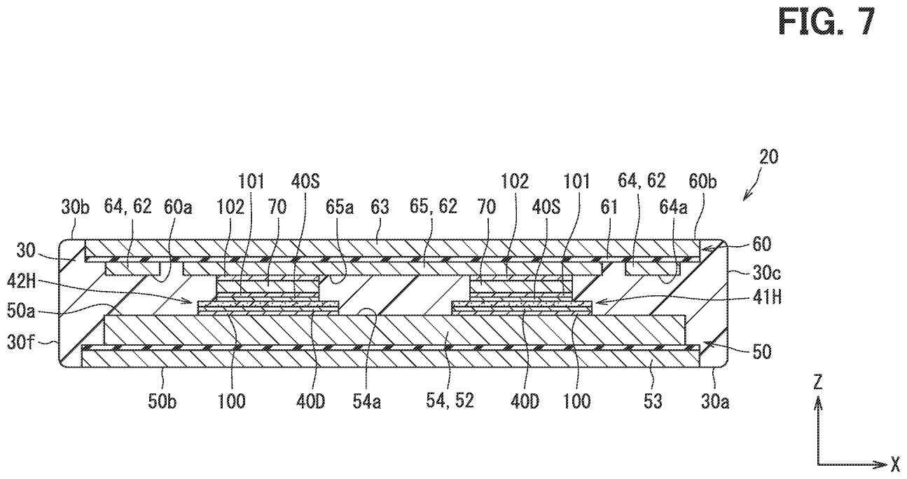

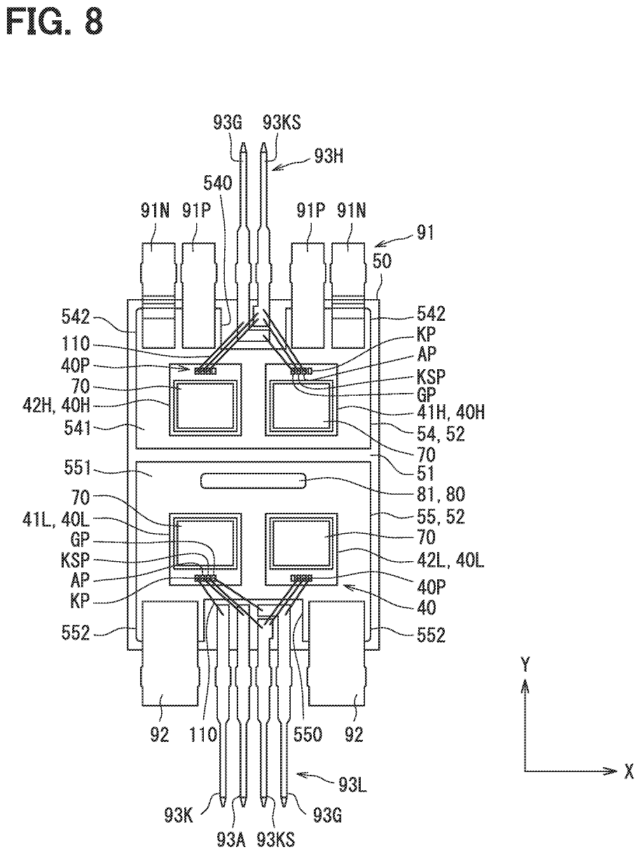

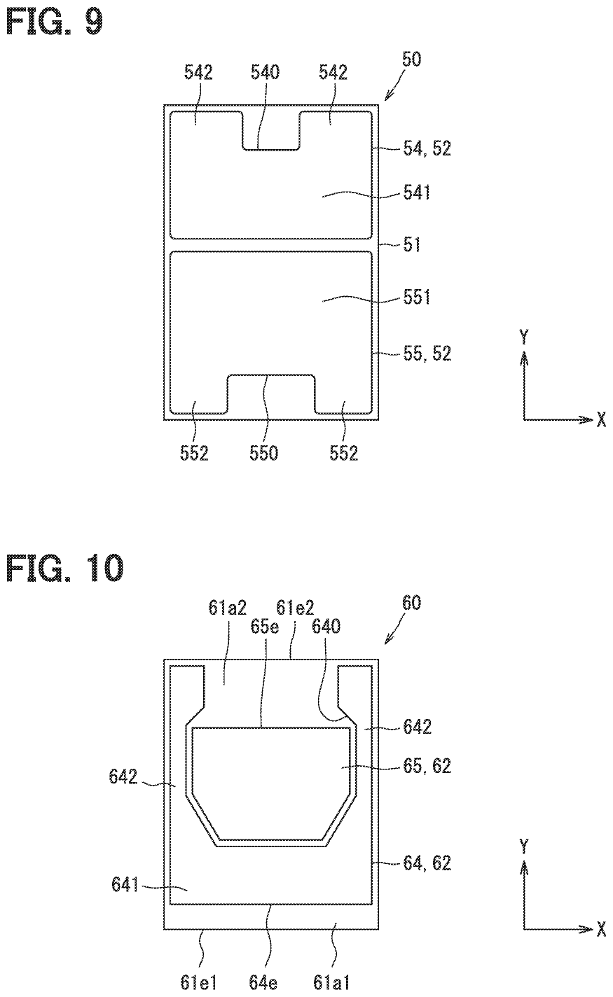

Next, the semiconductor device will be described with reference to FIGS. 2 to 10. FIG. 2 is a perspective view of the semiconductor device 20. FIG. 3 is a plan view of the semiconductor device when viewed along a direction Z1 in FIG. 2. FIG. 3 is a transparent view showing the internal structure. A region covered with the sealing body 30 is indicated by a broken line. FIG. 4 is a cross-sectional view taken along a line IV-IV in FIG. 3. FIG. 5 is a cross-sectional view taken along a line V-V in FIG. 3. FIG. 6 is a cross-sectional view taken along a line VI-VI in FIG. 3. FIG. 7 is a cross-sectional view taken along a line VII-VII in FIG. 3. FIG. 8 is a plan view of a substrate 50 on which a semiconductor element 40 is mounted. FIG. 8 is the view in which a sealing body 30 and a substrate 60 are removed from FIG. 3. FIG. 9 is a plan view showing a circuit pattern of a front surface metal body 52 on the substrate 50. FIG. 10 is a plan view showing a circuit pattern of a front surface metal body 62 on the substrate 60.

Hereinafter, a thickness direction of the semiconductor element 40 (semiconductor substrate) is referred to as a Z direction. An arrangement direction in which multiple semiconductor elements 40 are arranged side by side is referred to as an X direction. The arrangement direction is orthogonal to the Z direction. In the present embodiment, the X direction is the arrangement direction of the semiconductor elements 40 that are connected in parallel. A direction orthogonal to both the Z direction and the X direction is referred to as a Y direction. Unless otherwise specified, a shape when viewed in the Z direction, that is, a shape along an XY plane defined by the X direction and Y direction is referred to as a planar shape. A plan view when viewed in the Z direction may be simply referred to as a plan view.

As shown in FIGS. 2 to 10, the semiconductor device 20 constitutes one upper-lower arm circuit 9 as described above, that is, the upper-lower arm circuit 9 for one phase. The semiconductor device 20 includes a sealing body 30, a semiconductor element 40, substrates 50 and 60, a conductive spacer 70, an arm connection portion 80, and an external connection terminal 90. The semiconductor device 20 may be referred to as a semiconductor module, a power card, or the like.

The sealing body 30 seals a part of other elements constituting the semiconductor device 20. A remaining part of the other elements is exposed to the outside of the sealing body 30. The sealing body 30 is made of, for example, a resin. An example of the resin is an epoxy resin. The sealing body 30 is made of a resin and molded by, for example, a transfer molding method. Such a sealing body 30 may be referred to as a sealing resin body, a mold resin, a resin molded body, or the like. The sealing body 30 may be formed using gel, for example. The gel is filled (disposed), for example, in a facing region between the pair of substrates 50 and 60.

As shown in FIGS. 2 to 4, the sealing body 30 has a substantially rectangular shape as the planar shape. The sealing body 30 has a first surface 30a and a second surface 30b which is a back surface opposite to the first surface 30a in the Z direction, as surfaces forming a contour. The first surface 30a and the second surface 30b are, for example, flat surfaces. In addition, the sealing body 30 has side surfaces 30c, 30d, 30e, and 30f, as surfaces connecting the first surface 30a and the second surface 30b. The side surface 30c is a surface from which the power supply terminal 91 and the signal terminal 93H of the external connection terminals 90 protrude. The side surface 30d is a surface opposite to the side surface 30c in the Y direction. The side surface 30d is a surface from which the output terminal 92 and the signal terminal 93L protrude. The side surfaces 30e and 30f are surfaces from which the external connection terminals 90 do not protrude. The side surface 30e is a surface opposite to the side surface 30f in the X direction.

The semiconductor element 40 is formed by forming a switching element on a semiconductor substrate made of silicon (Si), a wide bandgap semiconductor having a wider bandgap than silicon, or the like. Examples of the wide bandgap semiconductor include silicon carbide (SiC), gallium nitride (GaN), gallium oxide (Ga₂O₃) and diamond. The semiconductor element 40 may be referred to as a power element, a semiconductor chip, or the like.

The semiconductor element 40 of the present embodiment is configured by forming the above-described n-channel MOSFET 11 in a semiconductor substrate made of SiC. The MOSFET 11 has a vertical structure so that a main current flows in the thickness direction of the semiconductor element 40 (semiconductor substrate), that is, in the Z direction. The semiconductor element 40 has main electrodes of switching elements on both surfaces in the Z direction, which is the thickness direction of the semiconductor element 40. Specifically, the semiconductor element 40 has, as the main electrodes, a drain electrode 40D on a first surface, and a source electrode 40S on a second surface which is a back surface opposite to the first surface in the Z direction. The main current flows between the drain electrode 40D and the source electrode 40S.

In a case where the diode 12 is a parasitic diode, the source electrode 40S also serves as an anode electrode, and the drain electrode 40D also serves as a cathode electrode. The diode 12 may be formed on a chip separate from the MOSFET 11. The drain electrode 40D is a main electrode on the high potential side, and the source electrode 40S is a main electrode on the low potential side.

The semiconductor element 40 has substantially a rectangular shape as the planar shape. For example, the semiconductor element 40 has a square shape, as the planar shape. As shown in FIGS. 3 and 8, the semiconductor element 40 has a pad 40P, which serves as a signal electrode, on the second surface. The pad 40P is formed at a position different from the source electrode 40S on the second surface. The pad 40P includes at least a gate pad. The semiconductor element 40 of the present embodiment has four pads 40P. As shown in FIG. 8, the pads 40P include a gate pad GP, a Kelvin source pad KSP, an anode pad AP, and a cathode pad KP.

The gate pad GP is a pad 40P for applying a drive voltage to the gate electrode of the MOSFET 11. That is, the gate pad GP is a gate electrode pad 40P that controls a main current flowing between the drain electrode 40D and the source electrode 40S, which are main electrodes. The Kelvin source pad KSP is a pad 40P for detecting the source potential of the MOSFET 11, that is, the potential of the source electrode 40S. The anode pad AP is a pad 40P for detecting an anode potential of a temperature sensitive diode (not shown) included in the semiconductor element 40. The cathode pad KP is a pad 40P for detecting the cathode potential of the temperature sensitive diode.

Among the pads 40P, the gate pad GP, the anode pad AP, and the cathode pad KP are electrically separated from the source electrode 40S. The Kelvin source pad KSP is electrically connected to the source electrode 40S. In the present embodiment, the gate pad GP, the Kelvin source pad KSP, the anode pad AP, and the cathode pad KP are arranged in this order in the X direction.

The source electrode 40S and the pad 40P are exposed from a protective film (not shown) that is formed on the second surface of the semiconductor substrate. The drain electrode 40D is formed on a substantially entire region on the first surface. The source electrode 40S is formed on a part of the second surface of the semiconductor element 40. In the plan view, the drain electrode 40D has a larger area than the source electrode 40S. The drain electrode 40D corresponds to a first main electrode, and the source electrode 40S corresponds to a second main electrode.

The semiconductor device 20 includes a plurality of semiconductor elements 40 having the above-described configuration. The plurality of semiconductor elements 40 include a semiconductor element 40H constituting the upper arm 9H and a semiconductor element 40L constituting the lower arm 9L. The semiconductor element 40H will also be referred to as an upper arm element, and the semiconductor element 40L will also be referred to as a lower arm element. The semiconductor element 40 of the present embodiment includes two semiconductor elements 40H and two semiconductor elements 40L.

The semiconductor element 40H includes a semiconductor element 41H as a first element and a semiconductor element 42H as a second element. The two semiconductor elements 40H (41H, 42H) are arranged in the X direction. The two semiconductor elements 40H, which are arranged in the X direction, have a common structure. The two semiconductor elements 40H having the common structure are arranged in the X direction and oriented in the same direction. The two semiconductor elements 40H are connected in parallel to each other.

The semiconductor element 40L includes a semiconductor element 41L as a first element and a semiconductor element 42L as a second element. The two semiconductor elements 40L (41L and 42L) are arranged in the X direction. The two semiconductor elements 40L, which are arranged in the X direction, have a common structure. The two semiconductor elements 40L having the common structure are arranged in the X direction and oriented in the same direction. The two semiconductor elements 40L are connected in parallel to each other.

In the present embodiment, all the semiconductor elements 40 have a common structure. The arrangement of the semiconductor elements 41H and 42H and the arrangement of the semiconductor elements 41L and 42L have two-fold symmetry around an axis along the Z direction. The semiconductor element 40H and the semiconductor element 40L are arranged in the Y direction. The semiconductor device 20 includes two rows of the semiconductor elements 40H and the semiconductor elements 40L along the Y direction.

The semiconductor elements 40 are disposed at substantially the same position in the Z direction. The drain electrode 40D of each semiconductor element 40 faces the substrate 50. The source electrode 40S of each semiconductor element 40 faces the substrate 60.

The substrates 50 and 60 are disposed so as to sandwich the plurality of semiconductor elements 40 therebetween in the Z direction. The substrates 50 and 60 are disposed such that at least portions thereof face each other in the Z direction. The substrates 50 and 60 encompass all of the plurality of semiconductor elements 40 (40H and 40L) in the plan view.

The substrate 50 is disposed on the drain electrode 40D side with respect to the semiconductor element 40. The substrate 60 is disposed on the source electrode 40S side with respect to the semiconductor element 40. The substrate 50 is electrically connected to the drain electrode 40D as described later, and provides a wiring function. Similarly, the substrate 60 is electrically connected to the source electrode 40S and provides a wiring function. Therefore, the substrates 50 and 60 may be referred to as wiring members, wiring substrates, or the like. The substrate 50 may be referred to as a drain substrate, and the substrate 60 may be referred to as a source substrate. The substrates 50 and 60 provide a heat dissipation function of dissipating heat generated by the semiconductor element 40. Therefore, the substrates 50 and 60 may be referred to as heat dissipation members. The substrate 50 corresponds to a first wiring member. The substrate 60 is a second wiring member electrically connected to the second main electrode.

The substrate 50 has a facing surface 50a facing the semiconductor element 40 and a back surface 50b opposite to the facing surface 50a. The substrate 50 includes an insulating base material 51, a front surface metal body 52, and a back surface metal body 53. The substrate 60 has a facing surface 60a facing the semiconductor element 40 and a back surface 60b opposite to the facing surface 60a. The substrate 60 includes an insulating base material 61, a front surface metal body 62, and a back surface metal body 63. Hereinafter, the front surface metal bodies 52 and 62 and the back surface metal bodies 53 and 63 may be simply referred to as metal bodies 52, 53, 62, and 63. The substrate 50 is a substrate in which the insulating base material 51 and the metal bodies 52 and 53 are stacked. The substrate 60 is a substrate in which the insulating base material 61 and the metal bodies 62 and 63 are stacked.

The insulating base material 51 electrically separates the front surface metal body 52 and the back surface metal body 53 from each other. Similarly, the insulating base material 61 electrically separates the front surface metal body 62 and the back surface metal body 63 from each other. The base materials 51 and 61 may be referred to as insulating layers. The material of the insulating base materials 51 and 61 is a resin or a ceramic of an inorganic material. As the resin, for example, an epoxy-based resin or a polyimide-based resin can be used. As the ceramic, for example, Al₂O₃(alumina), Si₃N₄ (silicon nitride), or the like can be used. When the insulating base materials 51 and 61 are resin, the substrates 50 and 60 may be referred to as metal-resin substrates. When the insulating base materials 51 and 61 are ceramic, the substrates 50 and 60 may be referred to as metal-ceramic substrates.

In the case of the insulating base materials 51 and 61 using a resin material, an inorganic filler may be contained in the resin material in order to improve heat dissipation property, insulation property, and the like. The linear expansion coefficient may be adjusted by adding a filler. As the filler, for example, Al₂O₃, SiO₂ (silicon dioxide), AlN (aluminum nitride), BN (boron nitride), or the like can be used. The insulating base materials 51 and 61 may contain only one type of filler or may contain a plurality of types of fillers.

In the case of the insulating base materials 51 and 61 using the resin-based material, the thickness of each of the insulating base materials 51 and 61, that is, the length in the Z direction is preferably about 50 μm to 300 μm in consideration of the heat dissipation property or the insulation property. In the case of the insulating base materials 51 and 61 using a ceramic material, the thickness of each of the insulating base materials 51 and 61 is preferably about 200 μm to 500 μm. In the Z direction, the front surfaces of the insulating base materials 51 and 61 are inner surfaces, that is, surfaces on the semiconductor element 40 side, and the back surfaces of the insulating base materials 51 and 61 opposite to the front surfaces in the Z direction are outer surfaces. The insulating base materials 51 and 61 may have a common (same) material configuration or may be different from each other. In the present embodiment, the resin-based insulating base materials 51 and 61 are employed, and the material configuration is common. The linear expansion coefficients of the insulating base materials 51 and 61 are adjusted to substantially the same value as that of the sealing body 30 by adding a filler to the resin. By adding the filler to the resin, the linear expansion coefficients of the insulating base materials 51 and 61 and the sealing body 30 are close to the linear expansion coefficient of the metal (Cu) constituting the metal bodies 52, 53, 62, and 63.

The metal bodies 52, 53, 62, 63 are provided, for example, as metal plates or metal foils. The metal bodies 52, 53, 62, and 63 are made of a metal having good electrical conductivity and thermal conductivity, such as Cu or Al. The thickness of each of the metal bodies 52, 53, 62, and 63 is, for example, about 0.1 mm to 3 mm. The front surface metal body 52 is disposed on the front surface of the insulating base material 51 in the Z direction. The back surface metal body 53 is disposed on the back surface of the insulating base material 51. Similarly, the front surface metal body 62 is disposed on the front surface of the insulating base material 61 in the Z direction. The back surface metal body 63 is disposed on the back surface of the insulating base material 61.

The thickness relationship between the front surface metal bodies 52 and 62 and the back surface metal bodies 53 and 63 is not particularly limited. The thickness of the front surface metal body 52 may be larger than that of the back surface metal body 53 or may be substantially equal to that of the back surface metal body 53. The thickness of the front surface metal body 52 may be smaller than that of the back surface metal body 53. Similarly, the thickness of the front surface metal body 62 may be larger than that of the back surface metal body 63 or may be substantially equal to that of the back surface metal body 63. The thickness of the front surface metal body 62 may be smaller than that of the back surface metal body 63. The relationship between the thicknesses of the front surface metal bodies 52 and 62 is not particularly limited, and the relationship between the thicknesses of the back surface metal bodies 53 and 63 is not particularly limited.

The front surface metal bodies 52 and 62 are patterned. The front surface metal bodies 52 and 62 provide wirings, that is, a circuit. Therefore, the front surface metal bodies 52 and 62 may be each referred to as a circuit pattern, a wiring layer, a circuit conductor, or the like. The front surface metal bodies 52 and 62 may each include a plating film such as a Ni-based plating film or an Au plating film on the metal surface. The pattern of the front surface metal bodies 52 and 62 may be referred to as a circuit pattern. The surface of the front surface metal body 52 and a non-arrangement region of the front surface of the insulating base material 51 on which the front surface metal body 52 is not arranged form the facing surface 50a of the substrate 50. Similarly, the surface of the front surface metal body 62 and a non-arrangement region of the front surface of the insulating base material 61 on which the front surface metal body 62 is not arranged form the facing surface 60a of the substrate 60.

For example, the substrates 50 and 60 may be formed by preparing the front surface metal bodies 52 and 62 patterned into a predetermined shape by press working, etching, or the like, and bringing the front surface metal bodies 52 and 62 into close contact with the stacked bodies of the two-layer structures of the insulating base materials 51 and 61 and the back surface metal bodies 53 and 63, respectively. After forming the stacked bodies having a three-layer structure of the front surface metal bodies 52 and 62, the insulating base materials 51 and 61, and the back surface metal bodies 53 and 63, the front surface metal bodies 52 and 62 may be patterned by cutting or etching.

As shown in FIGS. 8 and 9, the front surface metal body 52 includes a P wiring 54 and a relay wiring 55. The P wiring 54 and the relay wiring 55 are electrically separated by a predetermined interval (gap). The gap is filled with the sealing body 30. As surfaces on the semiconductor element 40 side in the Z direction, the P wiring 54 has a facing surface 54a, and the relay wiring 55 has a facing surface 55a. The facing surfaces 54a and 55a provide the facing surface 50a described above.

The P wiring 54 is connected to a P terminal 91P described later and the drain electrode 40D of the semiconductor element 40H. The P wiring 54 electrically connects the P terminal 91P and the drain electrode 40D of the semiconductor element 40H to each other. The P wiring 54 electrically connects the drain electrode 40D of the semiconductor element 41H and the drain electrode 40D of the semiconductor element 42H to each other.

The relay wiring 55 is connected to the drain electrode 40D of the semiconductor element 40L, the arm connection portion 80, and the output terminal 92. The relay wiring 55 electrically connects the arm connection portion 80 and the drain electrode 40D of the semiconductor element 40L to each other. The relay wiring 55 electrically connects the source electrode 40S of the semiconductor element 40H and the drain electrode 40D of the semiconductor element 40L to the output terminal 92. The relay wiring 55 electrically connects the drain electrode 40D of the semiconductor element 41L and the drain electrode 40D of the semiconductor element 42L to each other.

The P wiring 54 and the relay wiring 55 are arranged side by side in the Y direction. In the Y direction, the P wiring 54 is disposed on the power supply terminal 91 side, and the relay wiring 55 is disposed on the output terminal 92 side. The P wiring 54 is disposed on the side surface 30c side of the sealing body 30, and the relay wiring 55 is disposed on the side surface 30d side.

The P wiring 54 has a notch 540. The notch 540 is opened in one of four sides of a substantially rectangular shape in the plan view having the X direction as a longitudinal direction. The notch 540 is provided substantially at the center in the X direction on the side facing the side surface 30c. The P wiring 54 has a base portion 541 and a pair of extension portions 542. The base portion 541 and the pair of extension portions 542 define the notch 540. The P wiring 54 has a substantially U shape (recessed shape) in the plan view.

The base portion 541 is a portion closer to the relay wiring 55 than the notch 540 and the extension portions 542 in the Y direction, and has a substantially rectangular shape in the plan view. The base portion 541 overlaps the semiconductor element 40H in the plan view. That is, the two semiconductor elements 40H (41H, 42H) are disposed on the base portion 541. The drain electrode 40D of each of the semiconductor elements 40H is connected to the base portion 541.

The two extension portions 542 extend from the base portion 541 in the same direction, specifically, in the Y direction toward the side surface 30c of the sealing body 30. One of the extension portions 542 is connected to the vicinity of one end of the base portion 541 in the X direction, and the other of the extension portions 542 is connected to the vicinity of the other end of the base portion 541 in the X direction. The end portions of the U-shape of the P wiring 54, that is, the end portions of the two extension portions 542 opposite to the base portion 541 are both located at substantially the same position in the Y direction. The pair of extension portions 542 interpose the notch 540 in the X direction. The length of the base portion 541 in the Y direction is longer than the depth of the notch 540 and the extension portions 542.

The relay wiring 55 also has a notch 550. The notch 550 is opened in one of four sides of the substantially rectangular shape in the plan view. The notch 550 is provided substantially at the center in the X direction on the side facing the side surface 30d. That is, in the front surface metal body 52, the notch 540 is provided in one end portion in the Y direction, and the notch 550 is provided in the other end portion.

The relay wiring 55 includes a base portion 551 and a pair of extension portions 552. The base portion 551 and the pair of extension portions 552 define the notch 550. The relay wiring 55 has a substantially U shape (recessed shape) in the plan view. The base portion 551 is a portion closer to the P wiring 54 than the notch 550 and the extension portions 552 in the Y direction, and has a substantially rectangular shape in the plan view. The base portion 551 overlaps the semiconductor element 40L in the plan view. That is, the two semiconductor elements 40L (41L, 42L) are disposed on the base portion 551. The drain electrode 40D of each of the semiconductor elements 40L is connected to the base portion 551.

The two extension portions 552 extend from the base portion 551 in the same direction, specifically, in the Y direction toward the side surface 30d of the sealing body 30. One of the extension portions 552 is connected to the vicinity of one end of the base portion 551 in the X direction, and the other of the extension portions 552 is connected to the vicinity of the other end of the base portion 551. The end portions of the U-shape of the relay wiring 55, that is, the end portions of the two extension portions 552 opposite to the base portion 551 are both located at substantially the same position in the Y direction. The pair of extension portions 552 interpose the notch 550 in the X direction. The length of the base portion 551 in the Y direction is longer than the depth of the notch 550 and the extension portions 552.

As shown in FIGS. 3 and 10, the front surface metal body 62 includes an N wiring 64 and a relay wiring 65. The N wiring 64 and the relay wiring 65 are electrically separated by a predetermined interval (gap). The gap is filled with the sealing body 30. As surfaces on the semiconductor element 40 side in the Z direction, the N wiring 64 has a facing surface 64a, and the relay wiring 65 has a facing surface 65a. The facing surfaces 64a and 65a form the facing surface 60a described above.

The N wiring 64 is connected to an N terminal 91N described later and the source electrode 40S of the semiconductor element 40L. The N wiring 64 electrically connects the N terminal 91N and the source electrode 40S of the semiconductor element 40L. The N wiring 64 electrically connects the source electrode 40S of the semiconductor element 41L and the source electrode 40S of the semiconductor element 42L. The N wiring 64 may be referred to as a negative electrode wiring, a low potential power supply wiring, or the like.

The relay wiring 65 is connected to the source electrode 40S of the semiconductor element 40H and the arm connection portion 80. The relay wiring 65 electrically connects the source electrode 40S of the semiconductor element 40H and the arm connection portion 80 to each other. The relay wiring 65 electrically connects the source electrode 40S of the semiconductor element 41H and the source electrode 40S of the semiconductor element 42H to each other.

The N wiring 64 also has a notch 640. The notch 640 is opened in one of four sides of the substantially rectangular shape in the plan view. The notch 640 is provided substantially at the center in the X direction on the side facing the side surface 30c. The N wiring 64 has a base portion 641 and a pair of extension portions 642. The base portion 641 and the pair of extension portions 642 define the notch 640. The N wiring 64 has a substantially U shape (recessed shape) in the plan view.

The base portion 641 is a portion closer to the side surface 30d than the notch 640 and the extension portion 642 in the Y direction. The base portion 641 has a substantially rectangular shape in the plan view having the longitudinal direction along the X direction. The base portion 641 is arranged side by side with the relay wiring 65 in the Y direction. The base portion 641 overlaps the relay wiring 55 in the plan view. The source electrode 40S of each of the semiconductor elements 40L is connected to the base portion 641.

The two extension portions 642 extend from the base portion 641 in the same direction, specifically, in the Y direction toward the side surface 30c of the sealing body 30. One of the extension portions 642 is connected to the vicinity of one end of the base portion 641 in the X direction, and the other of the extension portions 642 is connected to the vicinity of the other end of the base portion 641. The end portions of the U-shape of the N wiring 64, that is, the end portions of the two extension portions 642 opposite to the base portion 641 are located at substantially the same position in the Y direction.

The pair of extension portions 642 form both ends of the front surface metal body 62 in the X direction. The pair of extension portions 642 are disposed near the ends of the substrate 60. In the plan view, a part of each of the pair of extension portions 642 overlaps the P wiring 54. In the Y direction, the extension portions 642 are longer than the base portion 641.

As described above, the relay wiring 65 is arranged side by side with the N wiring 64, specifically, the base portion 641 in the Y direction. In the Y direction, the relay wiring 65 is disposed at a position close to the side surface 30c of the sealing body 30, and the base portion 641 is disposed at a position close to the side surface 30d. The relay wiring 65 is disposed between the pair of extension portions 642 in the X direction. The relay wiring 65 is interposed between the pair of extension portions 642. The relay wiring 65 is disposed in the notch 640. The relay wiring 65 is disposed with a predetermined interval (gap) from the N wiring 64. In the plan view, a part of the relay wiring 65 overlaps the P wiring 54, and another part of the relay wiring 65 overlaps the relay wiring 55. The source electrode 40S of each of the semiconductor elements 40H is connected to the relay wiring 65. Details of the arrangement of the front surface metal body 62 (the N wiring 64 and the relay wiring 65) will be described later.

The back surface metal bodies 53 and 63 are electrically separated from the circuit including the semiconductor element 40 and the front surface metal bodies 52 and 62 by the insulating base materials 51 and 61. The back surface metal bodies 53 and 63 may be referred to as metal base substrates. The heat generated by the semiconductor element 40 is transmitted to the back surface metal bodies 53 and 63 via the front surface metal bodies 52 and 62 and the insulating base materials 51 and 61. The back surface metal bodies 53 and 63 each provide a heat dissipation function.

The back surface metal bodies 53 and 63 of the present embodiment each have a substantially rectangular shape as the planar shape. The back surface metal bodies 53 and 63 are so-called solid conductors disposed on substantially the entire back surfaces of the insulating base materials 51 and 61. As described above, since the linear expansion coefficients of the insulating base materials 51 and 61 are adjusted by the addition of the filler, the warpage can be suppressed even when the pattern is changed between the front and back sides. Of course, the back surface metal bodies 53 and 63 may be patterned so as to coincide with the front surface metal bodies 52 and 62 in the plan view.

The back surface metal bodies 53 and 63 of the present embodiment are disposed on substantially the entire back surfaces of the corresponding insulating base materials 51 and 61. In order to further enhance the heat dissipation effect, at least one of the back surface metal bodies 53 and 63 may be exposed from the sealing body 30. In the present embodiment, the back surface metal body 53 is exposed from the first surface 30a of the sealing body 30, and the back surface metal body 63 is exposed from the second surface 30b of the sealing body 30. The exposed surface of the back surface metal body 53 is substantially flush with the first surface 30a. The exposed surface of the back surface metal body 63 is substantially flush with the second surface 30b. The back surface metal bodies 53 and 63 form the back surfaces 50b and 60b of the substrates 50 and 60.

The conductive spacer 70 provides a spacer function of securing a predetermined interval between the semiconductor element 40 and the substrate 60. The conductive spacer 70 secures the height for a wire electrically connecting the corresponding signal terminal 93 to the pad 40P of the semiconductor element 40. The conductive spacer 70 is located in the middle of an electric conduction and heat conduction path between the source electrode 40S of the semiconductor element 40 and the substrate 60, and provides a wiring function and a heat dissipation function. The conductive spacer 70 contains a metal material having good electrical conductivity and thermal conductivity, such as copper (Cu). The conductive spacer 70 may include a plating film on its surface.

The conductive spacer 70 may be referred to as a terminal, a terminal block, a metal block body, or the like. The semiconductor device 20 includes the same number of conductive spacers 70 as the semiconductor elements 40. Specifically, the semiconductor device 20 includes four conductive spacers 70. The conductive spacers 70 are individually connected to the semiconductor elements 40. The conductive spacer 70 is a columnar body having a size substantially equal to or slightly smaller than that of the source electrode 40S in the plan view.

The arm connection portion 80 electrically connects the relay wirings 55 and 65. That is, the arm connection portion 80 electrically connects the upper arm 9H and the lower arm 9L. The arm connection portion 80 is provided between the semiconductor element 40H and the semiconductor element 40L in the Y direction. The arm connection portion 80 is provided in an overlapping region between the relay wiring 55 and the relay wiring 65 in the plan view. The arm connection portion 80 of the present embodiment includes a joint portion 81 and a bonding material 103 described later.

The joint portion 81 is a metal columnar body provided separately from the front surface metal bodies 52 and 62. Such a joint portion 81 may be referred to as a joint terminal. In the Z direction, the bonding material 103 is interposed between one of the end portions of the joint portion 81 and the relay wiring 55, and the bonding material 103 is interposed between the other one of the end portions of the joint portion 81 and the relay wiring 65.

Alternatively, the joint portion 81 may be integrally connected to at least one of the front surface metal body 52 or the front surface metal body 62. That is, the joint portion 81 may be provided integrally with the front surface metal bodies 52 and 62 as a part of the substrates 50 and 60. For example, the joint portion 81 is provided as a protrusion of the front surface metal body 62 (relay wiring 65). The arm connection portion 80 may not include the joint portion 81. That is, the arm connection portion 80 may include only the bonding material 103.

The external connection terminal 90 is a terminal for electrically connecting the semiconductor device 20 to an external device. The external connection terminal 90 is formed using a metal material having good conductivity such as copper. The external connection terminal 90 is, for example, a plate member. The external connection terminal 90 may be referred to as a lead. The external connection terminal 90 includes a power supply terminal 91, an output terminal 92, and a signal terminal 93. The power supply terminal 91 includes a P terminal 91P and an N terminal 91N. The P terminal 91P, the N terminal 91N, and the output terminal 92 are main terminals electrically connected to the main electrode of the semiconductor element 40. The signal terminal 93 includes a signal terminal 93H on the upper arm 9H side and a signal terminal 93L on the lower arm 9L side.

The power supply terminal 91 is an external connection terminal 90 electrically connected to the power supply lines 7 and 8 described above. The P terminal 91P is electrically connected to the positive electrode terminal of the smoothing capacitor 5. The P terminal 91P may be referred to as a positive electrode terminal, a high potential power supply terminal, or the like. The P terminal 91P is connected to the P wiring 54 of the front surface metal body 52. That is, the P terminal 91P is connected to the drain electrode 40D of the semiconductor element 40H constituting the upper arm 9H.

The P terminal 91P is connected to the vicinity of one end of the P wiring 54 in the Y direction. The P terminal 91P extends in the Y direction from a connection portion (bonding portion) with the P wiring 54, and protrudes to the outside of the sealing body 30 from the vicinity of the center of the side surface 30c in the Z direction. The semiconductor device 20 of the present embodiment includes two P terminals 91P. As shown in FIG. 8, one of the P terminals 91P is connected to one of the pair of extension portions 542, and the other one of the P terminals 91P is connected to the other one of the pair of extension portions 542. The P terminal 91P is disposed at a position close to the notch 540, that is, on the inner side in each of the extension portions 542 so as to be adjacent to the N terminal 91N in the plan view. The two P terminals 91P are arranged side by side in the X direction. The two P terminals 91P are disposed at substantially the same position in the Z direction.

The N terminal 91N is electrically connected to the negative electrode terminal of the smoothing capacitor 5. The N terminal 91N may be referred to as a negative electrode terminal, a low potential power supply terminal, or the like. The N terminal 91N is connected to the N wiring 64 of the front surface metal body 62. That is, the N terminal 91N is connected to the source electrode 40S of the semiconductor element 40L constituting the lower arm 9L.

The N terminal 91N is connected to the vicinity of one end of the N wiring 64 in the Y direction. The N terminal 91N extends in the Y direction from the bonding portion with the N wiring 64, and protrudes to the outside of the sealing body 30 from the vicinity of the center of the side surface 30c in the Z direction. The semiconductor device 20 includes two N terminals 91N. One of the N terminals 91N is connected to one of the pair of extension portions 642, and the other one of the N terminals 91N is connected to the other one of the pair of extension portions 642. The two N terminals 91N are arranged side by side in the X direction. The two N terminals 91N are disposed at substantially the same position in the Z direction.

The two N terminals 91N are disposed on the outer side of the two P terminals 91P in the X direction. In the plan view, one of the N terminals 91N is disposed close to one of the P terminals 91P, and the other one of the N terminals 91N is disposed close to the other one of the P terminals 91P. Side surfaces of the N terminal 91N and the P terminal 91P adjacent to each other in the X direction face each other at a part including a portion protruding from the sealing body 30.

The output terminal 92 is electrically connected to the winding 3a (stator coil) of the corresponding phase of the motor generator 3. The output terminal 92 may be referred to as an O terminal, an AC terminal, or the like. As shown in FIGS. 3 and 8, the output terminal 92 is connected to the relay wiring 55 of the front surface metal body 52 of the substrate 50. That is, the output terminal 92 is connected to a connection point between the upper arm 9H and the lower arm 9L.

The output terminal 92 is connected to the vicinity of one end of the relay wiring 55 in the Y direction. The output terminal 92 extends in the Y direction from the bonding portion with the relay wiring 55, and protrudes to the outside of the sealing body 30 from the vicinity of the center in the Z direction on the side surface 30d. The semiconductor device 20 includes two output terminals 92. One of the output terminals 92 is connected to one of the pair of extension portions 552, and the other of the output terminals 92 is connected to the other one of the pair of extension portions 552. The two output terminals 92 are arranged side by side in the X direction. The two output terminals 92 are disposed at substantially the same position in the Z direction.

The signal terminals 93 are electrically connected to a circuit board (not shown) including a drive circuit. The signal terminal 93H is electrically connected to the pad 40P of the semiconductor element 40H via the bonding wire 110. The number of the signal terminals 93H is not particularly limited. The signal terminal 93H includes at least a terminal for applying a drive voltage to at least the gate electrode of the semiconductor element 40H. The semiconductor device 20 of the present embodiment includes two signal terminals 93H. The signal terminals 93H are disposed at a position overlapping the notch 540 of the P wiring 54 in the plan view. In the signal terminal 93H, a bonding portion with the bonding wire 110 faces not the front surface metal body 52 but the insulating base material 51. The two signal terminals 93H are arranged side by side in the X direction.

The signal terminal 93H extends in the Y direction from the bonding portion with the bonding wire 110, and protrudes to the outside of the sealing body 30 from the vicinity of the center of the side surface 30c in the Z direction. At least a part of the protruding portion of the signal terminal 93H extends in the same direction as the power supply terminal 91. The signal terminal 93H is disposed between the two P terminals 91P in the X direction. That is, the external connection terminals 90 protruding from the side surface 30c are arranged in the order of the N terminal 91N, the P terminal 91P, the two signal terminals 93H, the P terminal 91P, and the N terminal 91N in the X direction.

The signal terminals 93H include a gate terminal 93G and a Kelvin source terminal 93KS. The two signal terminals 93H are arranged in the order of the gate terminal 93G and the Kelvin source terminal 93KS in the direction from the semiconductor element 42H toward the semiconductor element 41H. The gate terminal 93G is connected to the gate pad GP of each semiconductor element 40H via a bonding wire 110. The Kelvin source terminal 93KS is connected to the Kelvin source pad KSP of each semiconductor element 40H via a bonding wire 110.

The signal terminal 93L is electrically connected to the pad 40P of the semiconductor element 40L via the bonding wire 110. The signal terminal 93L includes at least a terminal for applying a drive voltage to the gate electrode of the semiconductor element 40L. The semiconductor device 20 of the present embodiment includes four signal terminals 93L. The signal terminals 93L are disposed at a position overlapping the notch 550 of the relay wiring 55 in the plan view. In the signal terminal 93L, the bonding portion with the bonding wire 110 faces not the front surface metal body 52 but the insulating base material 51. The four signal terminals 93L are arranged side by side in the X direction.

The signal terminal 93L extends in the Y direction from the bonding portion with the bonding wire 110, and protrudes to the outside of the sealing body 30 from the vicinity of the center in the Z direction on the side surface 30d. At least a part of the protruding portion of the signal terminal 93L extends in the same direction as the output terminal 92. The signal terminals 93L are disposed between the two output terminals 92 in the X direction. That is, the external connection terminals 90 protruding from the side surface 30d are arranged in the order of the output terminal 92, the four signal terminals 93L, and the output terminal 92 in the X direction. The four signal terminals 93L are arranged in a space defined between the output terminals 92.

The signal terminals 93L include a gate terminal 93G, a Kelvin source terminal 93KS, an anode terminal 93A, and a cathode terminal 93K. The four signal terminals 93L are arranged in the order of the gate terminal 93G, the Kelvin source terminal 93KS, the anode terminal 93A, and the cathode terminal 93K in the direction from the semiconductor element 42L toward the semiconductor element 41L. The arrangement of the four signal terminals 93L corresponds to the arrangement of the pads 40P of the semiconductor element 41L.

The gate terminal 93G is connected to the gate pad GP of each semiconductor element 40L via a bonding wire 110. The Kelvin source terminal 93KS is connected to the Kelvin source pad KSP of each semiconductor element 40L via a bonding wire 110. The anode terminal 93A is connected to the anode pad AP of the semiconductor element 41L via a bonding wire 110. The cathode terminal 93K is connected to the cathode pad KP of the semiconductor element 41L via a bonding wire 110.

As described above, the semiconductor device 20 includes the two signal terminals 93H and the four signal terminals 93L as the signal terminals 93. The signal terminals 93H are disposed so that the semiconductor element 40 is interposed between the signal terminals 93H and the signal terminals 93L in the Y direction. The two signal terminals 93H are arranged side by side in the X direction together with the four power supply terminals 91 (91P and 91N). The four signal terminals 93L are arranged side by side in the X direction together with the two output terminals 92. In order to suppress an increase in the size in the X direction, the semiconductor device 20 has two signal terminals 93H and four signal terminals 93L. Thus, the number of external connection terminals 90 is six on each of the side surface 30c side and the side surface 30d side.

In the configuration in which the plurality of semiconductor elements 40 are thermally connected to each other, it is also possible to guarantee the overheated state of the plurality of semiconductor elements 40 by using only the temperature sensitive diodes of some of the semiconductor elements 40. Therefore, only some of the plurality of semiconductor elements 40 may be connected to the anode terminal 93A and the cathode terminal 93K. In this case, the number of signal terminals 93 can be reduced. However, if the temperature sensitive diodes that are not connected to the anode terminal 93A and the cathode terminal 93K are set in a so-called floating state in which the temperature sensitive diodes float in potential, there is a concern that a defect may occur in the semiconductor element 40.

In the present embodiment, the Kelvin source terminal 93KS, which is the signal terminal 93H, is connected to the anode pad AP of each semiconductor element 40H via the bonding wire 110 in order to suppress the temperature sensitive diode from being in the floating state in terms of potential. Alternatively, the Kelvin source terminal 93KS may be connected to the cathode pad KP of each semiconductor element 40H. Similarly, the Kelvin source terminal 93KS, which is the signal terminal 93L, is connected to the anode pad AP of the semiconductor element 42L via the bonding wire 110. Alternatively, the Kelvin source terminal 93KS may be connected to the cathode pad KP of the semiconductor element 42L.

The drain electrode 40D of the semiconductor element 40 is bonded to the front surface metal body 52 via the bonding material 100. The source electrode 40S of the semiconductor element 40 is bonded to the conductive spacer 70 via the bonding material 101. The conductive spacer 70 is bonded to the front surface metal body 62 via the bonding material 102. The joint portion 81 is bonded to the front surface metal bodies 52 and 62 via the bonding material 103. Among the external connection terminals 90, the P terminal 91P, the N terminal 91N, and the output terminal 92, which are main terminals, are bonded to the front surface metal bodies 52 and 62 via the bonding material 104.

The bonding materials 100 to 104 have electrical conductivity. For example, solder can be adopted as the bonding materials 100 to 104. An example of the solder is a multi-component lead-free solder containing Cu, Ni, and the like in addition to Sn. Instead of the solder, a sintered bonding member such as sintered silver may be used.

The P terminal 91P, the N terminal 91N, and the output terminal 92 may be directly bonded to the corresponding front surface metal bodies 52 and 62 without the bonding material 104. The P terminal 91P, the N terminal 91N, and the output terminal 92 may be directly bonded to the front surface metal bodies 52 and 62 by, for example, ultrasonic bonding, friction stir welding, laser welding, or the like. When the joint portion 81 is provided separately from the substrates 50 and 60, the joint portion 81 may be directly bonded to the front surface metal bodies 52 and 62.

As described above, in the semiconductor device 20, the plurality of semiconductor elements 40 constituting the upper-lower arm circuit 9 for one phase are sealed by the sealing body 30. The sealing body 30 integrally seals (covers) the plurality of semiconductor elements 40, a part of the substrate 50, a part of the substrate 60, the plurality of conductive spacers 70, the arm connection portion 80, and a part of each external connection terminal 90. The sealing body 30 seals the insulating base materials 51 and 61 and the front surface metal bodies 52 and 62 in the substrates 50 and 60.

The semiconductor element 40 is disposed between the substrates 50 and 60 in the Z direction. The semiconductor element 40 is interposed between the substrates 50 and 60 arranged to face each other. Accordingly, the heat of the semiconductor element 40 can be dissipated to both sides in the Z direction. The semiconductor device 20 has a double-sided heat dissipation structure. The back surface 50b of the substrate 50 is substantially flush with the first surface 30a of the sealing body 30. The back surface 60b of the substrate 60 is substantially flush with the second surface 30b of the sealing body 30. Since the back surfaces 50b and 60b are exposed surfaces, heat dissipation can be improved.

The two semiconductor elements 40H (41H and 42H) arranged side by side in the X direction are connected in parallel to each other by the front surface metal bodies 52 and 62, the conductive spacers 70, and the bonding materials 100 to 102. The two semiconductor elements 40L (41L and 42L) arranged side by side in the X direction are connected in parallel to each other by the surface metal bodies 52 and 62, the conductive spacers 70, and the bonding materials 100 to 102.

### <Arrangement of Front Surface Metal Body>

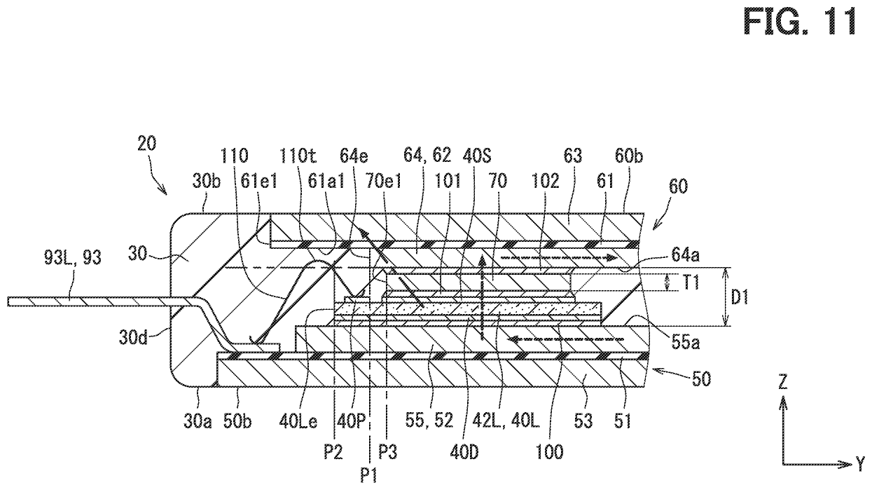

Next, the arrangement (pattern) of the front surface metal body 62 will be described with reference to FIGS. 3, 6, 10, and 11. FIG. 11 is an enlarged view of a region XI in FIG. 6. The front surface metal body 62 of the present embodiment is patterned so as to have a predetermined positional relationship with a part of other elements constituting the semiconductor device 20.

First, the N wiring 64 of the front surface metal body 62 will be described. As shown in FIGS. 3, 6, and 11, the semiconductor element 40L and the signal terminal 93L, which are electrically connected to each other via the bonding wire 110, are arranged in the Y direction. In the Y direction, an end portion 64e of the N wiring 64 is located between an end portion 70e1 of the conductive spacer 70 as the bonding target to which the N wiring 64 is bonded and an end portion 40Le of the semiconductor element 40L. Each of the end portions 40Le, 64e, and 70e1 described above is an end portion on the signal terminal 93L side in the Y direction. In the configuration including the conductive spacer 70, the bonding target of the N wiring 64 is the conductive spacer 70 bonded via the bonding material 102. The bonding target may be referred to as a connection target.

The end portion 64e of the N wiring 64 is located between the end portion 70e1 of the conductive spacer 70 connected to the semiconductor element 41L and the end portion 40Le of the semiconductor element 41L. Similarly, the end portion 64e of the N wiring 64 is located between the end portion 70e1 of the conductive spacer 70 connected to the semiconductor element 42L and the end portion 40Le of the semiconductor element 42L.

The end portion 64e of the N wiring 64 may be at a position closer to the end portion 70e1 of the conductive spacer 70 than the end portion 61e1 of the insulating base material 61 in the Y direction, or may be at a position substantially coincide with the position of the end portion 61e1 in the Y direction. The end portion 61e1 is an end portion on the signal terminal 93L side in the Y direction. The end portion 64e of the present embodiment is closer to the end 70e1 than the end 61e1. That is, the N wiring 64 is cut out. As shown in FIGS. 6, 10, and 11, the insulating base material 61 has an exposed portion 61a1 exposed from the front surface metal body 62. A top portion 110t of the bonding wire 110 connected to the signal terminal 93L faces the exposed portion 61a1 in the Z direction. The top portion 110t is closer to the insulating base material 61 than the facing surface 64a of the N wiring 64 in the Z direction. The top portion 110t is located between the end portion 40Le and the end portion 61e1 in the Y direction.

In FIG. 11, the position of the end portion 64e of the N wiring 64 in the Y direction is indicated by P1, the position of the end portion 40Le of the semiconductor element 40L is indicated by P2, and the position of the end portion 70e1 of the conductive spacer 70 is indicated by P3. The position P1 of the end portion 64e is between the position P2 of the end portion 40Le and the position P3 of the end portion 70e1.

The relay wiring 65 also has the same configuration as the N wiring 64. As shown in FIGS. 3 and 6, the semiconductor element 40H and the signal terminal 93H, which are electrically connected to each other via the bonding wire 110, are arranged in the Y direction. In the Y direction, the end portion 65e of the relay wiring 65 is located between the end portion 70e2 of the conductive spacer 70 as the bonding target to which the relay wiring 65 is bonded and the end portion 40He of the semiconductor element 40H. Each of the end portions 40He, 65e, and 70e2 described above is an end on the signal terminal 93H side in the Y direction. In the configuration including the conductive spacer 70, the bonding target of the relay wiring 65 is the conductive spacer 70 bonded via the bonding material 102.

The end portion 65e of the relay wiring 65 is located between the end portion 70e2 of the conductive spacer 70 connected to the semiconductor element 41H and the end portion 40He of the semiconductor element 41H. Similarly, the end portion 65e of the relay wiring 65 is located between the end portion 70e2 of the conductive spacer 70 connected to the semiconductor element 42H and the end portion 40He of the semiconductor element 42H.

The end portion 65e of the relay wiring 65 may be located closer to the end portion 70e2 of the conductive spacer 70 than the end portion 61e2 of the insulating base material 61 in the Y direction, or may be located at a position substantially coincide with the position of the end portion 61e2 in the Y direction. The end portion 61e2 is an end portion on the signal terminal 93H side in the Y direction. The end portion 65e of the present embodiment is closer to the end portion 70e2 than the end portion 61e2. That is, the relay wiring 65 is cut out. As shown in FIGS. 6 and 10, the insulating base material 61 has an exposed portion 61a2 exposed from the front surface metal body 62. The top portion 110t of the bonding wire 110 connected to the signal terminal 93H faces the exposed portion 61a2 in the Z direction. The top portion 110t is closer to the insulating base material 61 than the facing surface 65a of the relay wiring 65 in the Z direction. The top portion 110t is located between the end portion 40He and the end portion 61e2 in the Y direction.

### Summary of First Embodiment

In the present embodiment, the substrate 60 is used as the second wiring member electrically connected to the source electrode 40S, which is the second main electrode. The end portion 64e of the N wiring 64 is located between the end portion 70e1 of the conductive spacer 70, which is the bonding target of the N wiring 64, and the end portion 40Le of the semiconductor element 40L by the patterning of the front surface metal body 62 of the substrate 60. The end portion 65e of the relay wiring 65 is located between the end portion 70e2 of the conductive spacer 70, which is the bonding target of the relay wiring 65, and the end portion 40He of the semiconductor element 40H.

In this manner, the end portions 64e and 65e of the front surface metal body 62 are located more to inside than the corresponding end portions 40Le and 40He of the semiconductor element 40. As a result, contact between the front surface metal body 62 and the bonding wire 110 can be avoided, and the facing surfaces of the front surface metal body 62 of the substrate 60 and the front surface metal body 52 of the substrate 50 can be brought close to each other. For example, as shown in FIG. 11, the facing surface 55a of the relay wiring 55 and the facing surface 64a of the N wiring 64 can be brought close to each other. That is, it is possible to shorten a facing surface distance D1, which is a distance between the facing surfaces 55a and 64a in the Z direction.

The broken-line arrows shown in FIG. 11 indicate the flow of current. As described above, since the facing surfaces 55a and 64a are close to each other, the effect of magnetic flux cancellation by the currents flowing in opposite directions to each other is enhanced, and thus the inductance can be reduced. In addition, since the heat transfer path from the semiconductor element 40 to the front surface metal body 62 is shortened, the thermal resistance can be reduced.

In addition to the facing surfaces 55a and 64a, the facing surface 54a of the P wiring 54 and the facing surface 64a of the N wiring 64 can be brought close to each other. The facing surface 54a of the P wiring 54 and the facing surface 65a of the relay wiring 65 can be brought close to each other. The facing surface 55a of the relay wiring 55 and the facing surface 65a of the relay wiring 65 can be brought close to each other. Therefore, the inductance can be reduced. Further, it is possible to reduce the thermal resistance.

The heat spreads ideally at an angle of 45 degrees due to the presence of the heat transfer member. In the present embodiment, the end portions 64e and 65e of the front surface metal body 62 are located more to outside than the end portions 70e1 and 70e2 of the conductive spacer 70 as the bonding target of the front surface metal body 62. The heat of the semiconductor element 40 can be diffused to the outside of the conductive spacer 70 (bonding target) in the plan view through the front surface metal body 62. That is, in the present embodiment, the heat of the semiconductor element 40 is diffused in an ideal or nearly ideal state as indicated by the broken-line arrow in FIG. 11. Therefore, it is possible to reduce the thermal resistance. As described above, according to the semiconductor device 20 of the present embodiment, it is possible to reduce the thermal resistance while reducing the inductance.

In the present embodiment, the arrangement of the front surface metal body 62 described above is adopted in the configuration including the conductive spacer 70. Thus, the facing surfaces of the surface metal bodies 52 and 62 can be brought close to each other, that is, the thickness T1 of the conductive spacer 70 can be reduced. Since the conductive spacer 70 is thin, the thermal resistance can be reduced.

In the present embodiment, the top portion 110t of the bonding wire 110 connected to the signal terminal 93L faces the exposed portion 61a1 of the insulating base material 61 in the Z direction. The top portion 110t of the bonding wire 110 connected to the signal terminal 93H faces the exposed portion 61a2 of the insulating base material 61 in the Z direction. In other words, the insulating base material 61 (and the back surface metal body 63) is disposed up to the position outside of the end portions 64e and 65e of the front surface metal body 62. Accordingly, when heat is transferred from the front surface metal body 62 to the insulating base material 61 and the back surface metal body 63, the heat is also diffused to the outside of the front surface metal body 62 in the plan view. Therefore, the thermal resistance can be further reduced.

### Modification

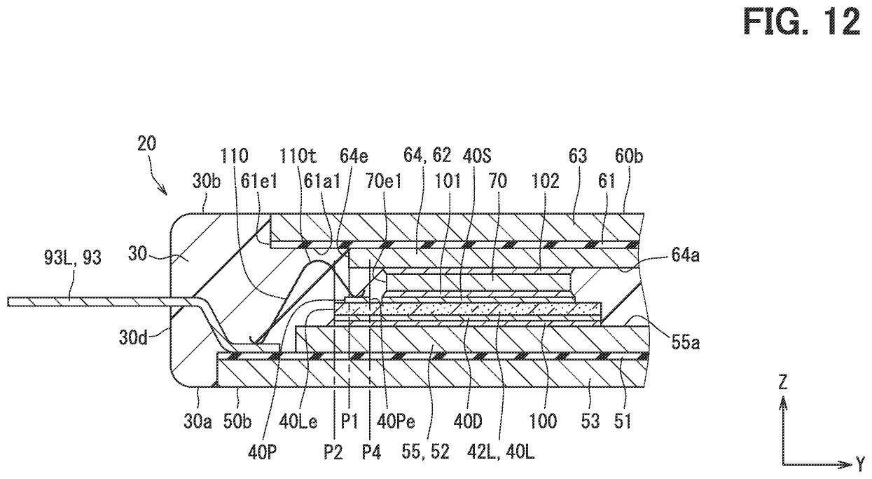

As shown in FIG. 12, the end portion 64e of the N wiring 64, which is the front surface metal body 62, may be located between the end portion 40Pe of the pad 40P of the semiconductor element 40L on the source electrode 40S side and the end portion 40Le of the semiconductor element 40L. FIG. 12 corresponds to FIG. 11. In FIG. 12, the position of the end portion 40Pe is indicated by P4. The position P1 of the end portion 64e is between the position P2 of the end portion 40Le and the position P4 of the end portion 40Pe. According to this, heat is easily diffused to the outside of the conductive spacer 70 (bonding target) in the plan view, and the thermal resistance can be further reduced.

The same applies to the end portion 65e of the relay wiring 65. Although not illustrated, the end portion 65e of the relay wiring 65 may be located between the end portion of the pad 40P of the semiconductor element 40H on the source electrode 40S side and the end portion 40He of the semiconductor element 40H.

Although an example in which the semiconductor device 20 includes the conductive spacer 70 has been described, the present disclosure is not limited thereto. A configuration may be adopted in which the conductive spacer 70 is not interposed between the semiconductor element 40 and the front surface metal body 62, and the front surface metal body 62 is bonded to the source electrode 40S via a bonding material. In this case, the metal body as the bonding target to which the front surface metal body 62 is bonded is the source electrode 40S.

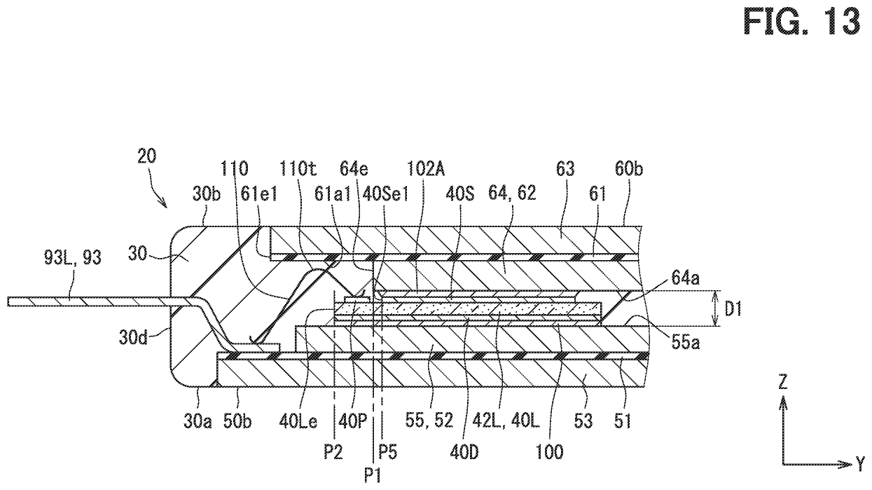

As shown in FIG. 13, the front surface metal body 62 may be thicker than the back surface metal body 63. FIG. 13 corresponds to FIG. 11. The thicker the front surface metal body 62 is, the shorter the distance D2 between the opposing surfaces can be. As a result, the effect of magnetic flux cancellation is enhanced, and the inductance can be further reduced. When the thickness of the front surface metal body 62 is increased, the conductive spacer 70 can be easily removed as shown in FIG. 13. In FIG. 13, the front surface metal body 62 is bonded to the source electrode 40S via the bonding material 102A. Of course, in the configuration including the conductive spacer 70, the front surface metal body 62 may be thicker than the back surface metal body 63.

As shown in FIG. 13, the end portion 64e of the N wiring 64 is located between the end portion 40Se1 of the source electrode 40S, which is the bonding target, and the end portion 40Le of the semiconductor element 40L. The end portion 40Se1 is an end portion on the signal terminal 93L side in the Y direction. In FIG. 13, the position of the end portion 40Se1 is indicated by P5. The position P1 of the end portion 64e is between the position P2 of the end portion 40Le and the position P5 of the end portion 40Se1. The end portion 65e of the relay wiring 65 is located between the end portion 40Se2 (see FIG. 3) of the source electrode 40S as the bonding target and the end portion 40He of the semiconductor element 40H. With such an arrangement, even in the configuration in which the bonding target is the source electrode 40S, the same effect as that of the configuration in which the bonding target is the conductive spacer 70 can be achieved.

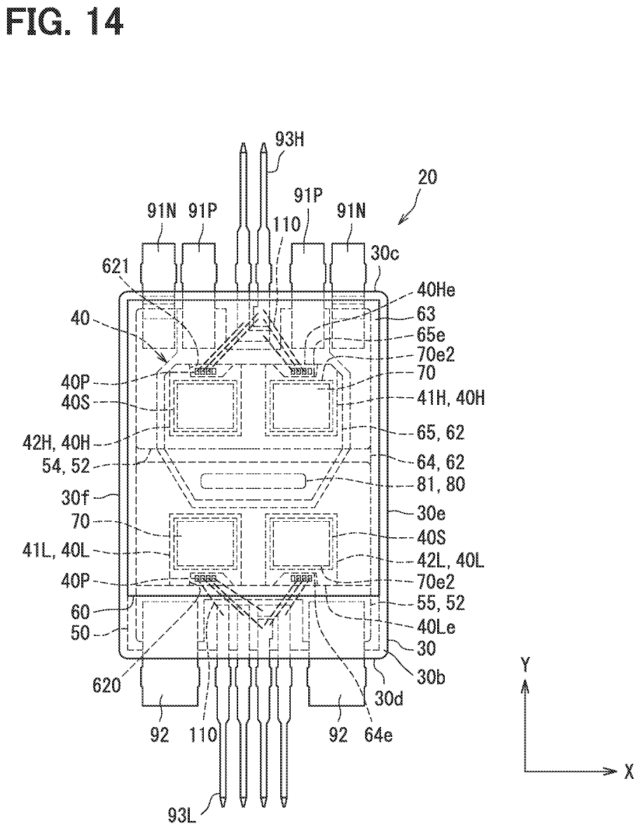

The end portions 64e and 65e of the front surface metal body 62 are not limited to the examples described above. For example, as shown in FIG. 14, the front surface metal body 62 may be formed with notches 620 and 621, and the above-described end portions 64e and 65e may be each provided by at least a part of side portions defining the corresponding notch 620 and 621. In FIG. 14, as an example, the bottom sides of the notches 620 and 621 are the end portions 64e and 65e.

The notch 620 is locally provided at an end portion of the N wiring 64 on the signal terminal 93L side so as to avoid contact with the bonding wire 110 connected to the signal terminal 93L. The notch 621 is locally provided at an end portion of the relay wiring 65 on the signal terminal 93H side so as to avoid contact with the bonding wire 110 connected to the signal terminal 93H. In this manner, the front surface metal body 62 may have a locally notched shape. According to this, it is possible to reduce the thermal resistance as compared with a shape in which the end portion is uniformly cut out.

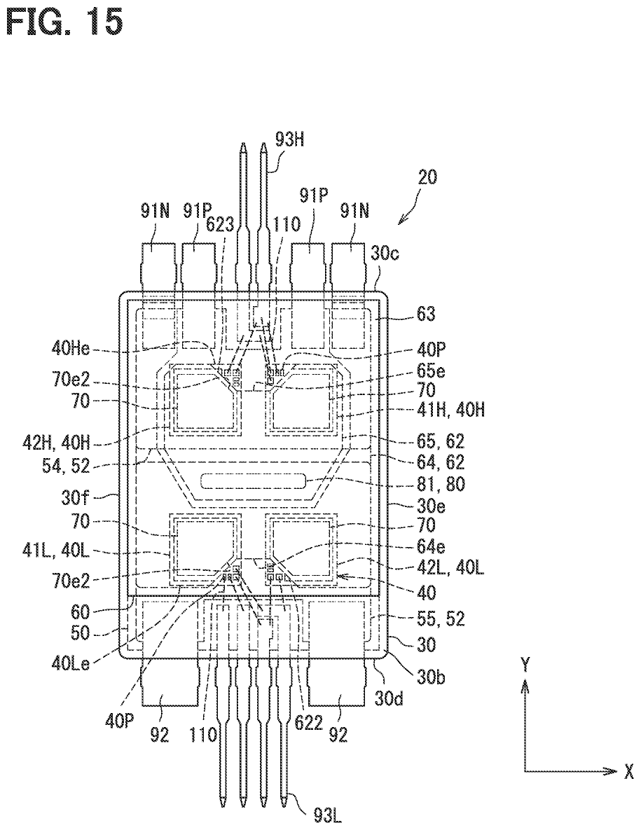

The arrangement of the pads 40P is not limited to the example described above. For example, as shown in FIG. 15, the pads 40P may be provided so as to be biased to the periphery of one of four corners of the semiconductor element 40 having a substantially rectangular planar shape. In the two semiconductor elements 40L having a common structure and arranged side by side in the X direction, the semiconductor element 42L is arranged to be rotated by 90 degrees with respect to the arrangement of the semiconductor element 41L. In the two semiconductor elements 40H having a common structure and arranged side by side in the X direction, the semiconductor element 42H is arranged so as to be rotated by 90 degrees with respect to the arrangement of the semiconductor element 41H. Each of the source electrode 40S and the conductive spacer 70 has a shape in which one of four corner portions of a substantially rectangular shape in the plan view is cut out so as to avoid the pads 40P.

In FIG. 15, in the arrangement of the pads 40P described above, notches 622 and 623 are formed in the front surface metal body 62, and the end portions 64e and 65e described above are each provided by at least a part of side portions defining the corresponding notch 622 and 623. The notch 622 is locally provided at the end portion of the N wiring 64 on the signal terminal 93L side so that the end portion 64e satisfies the above-described positional relationship while avoiding contact between the N wiring 64 and the bonding wire 110 connected to the signal terminal 93L. The notch 623 is locally provided at the end portion of the relay wiring 65 on the signal terminal 93H side so that the end portion 65e satisfies the above-described positional relationship while avoiding contact between the relay wiring 65 and the bonding wire 110 connected to the signal terminal 93H. In this way, by forming the front surface metal body 62 in the shape in which the front surface metal body 62 is locally cut out, even when the pads 40P are arranged unevenly, it is possible to reduce the thermal resistance while reducing the inductance.

### Second Embodiment

The present embodiment is a modification of the preceding embodiment as a basic configuration and may incorporate description of the preceding embodiment. In the preceding embodiment, the bonding wire 110 is provided so as not to be in contact with the insulating base material 61. Alternatively, the bonding wire 110 may be provided so as to be in contact with the insulating base material 61.

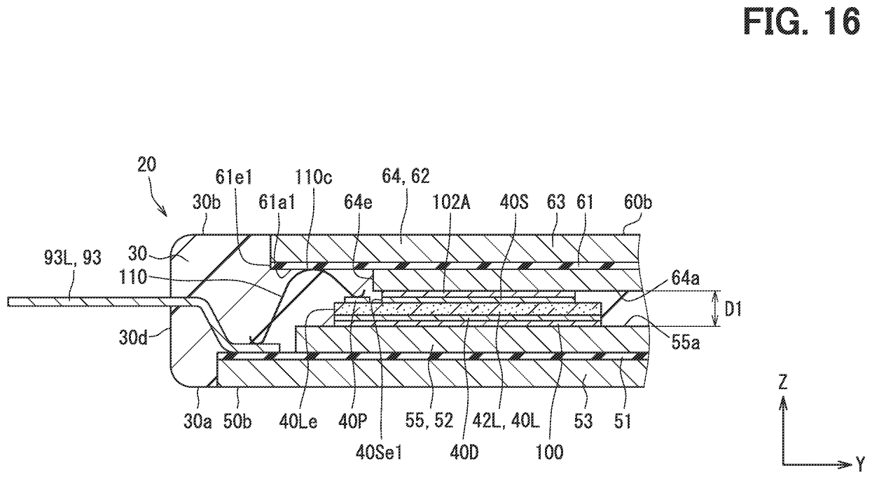

FIG. 16 is a cross-sectional view showing an example of the semiconductor device 20 according to the present embodiment. FIG. 16 corresponds to FIG. 11. In the semiconductor device 20 shown in FIG. 16, the bonding wire 110 is in contact with the insulating base material 61. The bonding wire 110 has a contact portion 110c that is a portion in contact with the insulating base material 61. The bonding wire 110 is pressed against the insulating base material 61 and deformed. By this deformation, the contact portion 110c extends substantially parallel to the surface of the insulating base material 61, for example. The bonding wire 110 connected to the signal terminal 93L is in contact with the exposed portion 61a1 of the insulating base material 61. Although not shown, the bonding wire 110 connected to the signal terminal 93H is in contact with the exposed portion 61a2 of the insulating base material 61.

The semiconductor device 20 does not include the conductive spacer 70. The front surface metal body 62 of the substrate 60 is bonded to the source electrode 40S, which is the bonding target, via the bonding material 102A. The N wiring 64 is bonded to the source electrode 40S of the semiconductor element 40L. Although not shown, the relay wiring 65 is bonded to the source electrode 40S of the semiconductor element 40H.

The other configurations are the same as the configurations described in the preceding embodiment. For example, the end portion 64e of the N wiring 64 is located between the end portion 40Se1 of the source electrode 40S, which is the bonding target, and the end portion 40Le of the semiconductor element 40L. Although not shown, the end portion 65e of the relay wiring 65 is located between the end portion 40Se2 of the source electrode 40S, which is the bonding target, and the end portion 40He of the semiconductor element 40H.

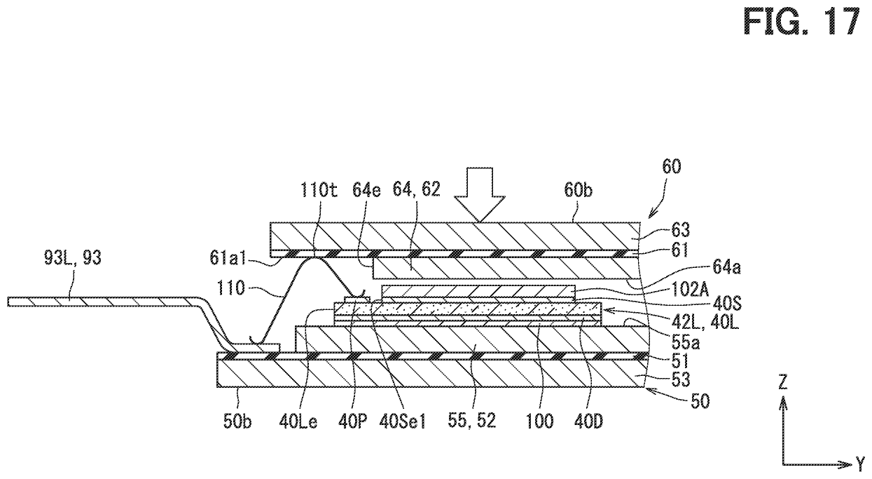

FIG. 17 is a cross-sectional view showing an example of a method for manufacturing the semiconductor device 20 shown in FIG. 16. FIG. 17 corresponds to FIG. 16. FIG. 17 shows a process of electrically connecting the semiconductor element 40 and the substrate 60.

First, each element constituting the semiconductor device 20 is prepared. In the present embodiment, the substrate 60 in which the front surface metal body 62 is patterned so that the end portions 64e and 65e satisfy the above-described positional relationship is prepared.

Next, a first connection step is performed. In this step, the semiconductor element 40 is disposed on the front surface metal body 52 of the substrate 50 such that the drain electrode 40D faces the front surface metal body 52. Then, the drain electrode 40D and the front surface metal body 52 are electrically connected to each other. In the present embodiment, the drain electrode 40D and the front surface metal body 52 are bonded by the bonding material 100. In the first connection step, the joint portion 81 and the front surface metal body 52 are bonded by the bonding material 103. The P terminal 91P and the output terminal 92 are bonded to the front surface metal body 52 by the bonding material 104.

Next, a wire bonding step is performed. In this step, the pads 40P of the semiconductor element 40 and the signal terminals 93 are bonded via the bonding wires 110. Specifically, the signal terminal 93L and the corresponding pad 40P of the semiconductor element 40L are connected via the bonding wire 110. The signal terminal 93H and the corresponding pad 40P of the semiconductor element 40H are connected via the bonding wire 110.

Next, a second connection step is performed. In this step, the source electrode 40S of the semiconductor element 40 and the substrate 60 as the second wiring member are electrically connected to each other. In the present embodiment, the source electrode 40S and the front surface metal body 62 are bonded via the bonding material 102A. At this time, the substrate 50 to which the semiconductor element 40 is connected and the substrate 60 are relatively displaced in directions in which the facing surfaces of the surface metal bodies 52 and 62 approach each other.

Due to this displacement, the exposed portions 61a1 and 61a2 of the insulating base material 61 exposed from the front surface metal body 62 come into contact with the top portion 110t of the bonding wire 110. As shown in FIG. 17, the exposed portion 61a1 of the insulating base material 61 is in contact with the bonding wire 110 connected to the signal terminal 93L. The exposed portion 61a2 of the insulating base material 61 is in contact with the bonding wire 110 connected to the signal terminal 93H.

Then, from the contact state, the facing surfaces of the surface metal bodies 52 and 62, for example, the facing surfaces 55a and 64a shown in FIG. 17 are further displaced in the approaching directions. The bonding wire 110 is pressed and deformed by the insulating base material 61 (substrate 60), and the height of the bonding wire 110 becomes lower than that at the time of wire bonding. In this deformed state, the source electrode 40S and the front surface metal body 62 are bonded to each other. In the second connection step, the joint portion 81 and the front surface metal body 62 are bonded to each other via the bonding material 103. The N terminal 91N and the front surface metal body 62 are bonded via the bonding material 104.

Next, a molding step of the sealing body 30 is performed. For example, the sealing body 30 is molded by the above-described transfer molding method. After the molding, for example, cutting is performed. The sealing body 30 is cut together with parts of the back surface metal bodies 53 and 63 of the substrates 50 and 60. Thus, the back surfaces 50b and 60b are exposed from the sealing body 30. The back surface 50b is substantially flush with the first surface 30a of the sealing body 30, and the back surface 60b is substantially flush with the second surface 30b. Note that the sealing body 30 may be molded in a state in which the back surfaces 50b and 60b are pressed against the cavity wall surface of the molding die and brought into close contact therewith. In this case, when the sealing body 30 is molded, the back surfaces 50b and 60b are exposed from the sealing body 30. Therefore, cutting after the molding is unnecessary.

Next, unnecessary portions such as tie bars are removed from the lead frame. In this way, the semiconductor device 20 described above can be obtained.

### Summary of Second Embodiment

The positions of the end portions 64e and 65e of the front surface metal body 62 in the present embodiment are the same as those in the preceding embodiment. Therefore, the same effects as those of the configurations described in the preceding embodiment can be achieved. That is, it is possible to reduce the thermal resistance while reducing the inductance.

In the present embodiment, as described above, the insulating base material 61 of the substrate 60 is pressed against the bonding wire 110 when the source electrode 40S and the front surface metal body 62 are bonded. The bonding wire 110 is pressed and deformed by the insulating base material 61 (substrate 60), and the height of the bonding wire 110 becomes lower than that at the time of wire bonding. With the configuration in which the bonding wires 110 are in contact with the exposed portions 61a1 and 60a2 of the insulating base material 61, the distance D1 between the facing surfaces can be further shortened. Thereby, it may be possible to reduce the inductance. In addition, the thermal resistance can be further reduced. In addition, a configuration in which the conductive spacer 70 is excluded can be easily obtained. For example, the conductive spacer 70 can be easily removed without increasing the thickness of the front surface metal body 62 as shown in FIG. 13.

Further, since the bonding wires 110 are held between the signal terminals 93, the pads 40P, and the insulating base material 61, it is possible to suppress the occurrence of wire sweep at the time of molding the sealing body 30.

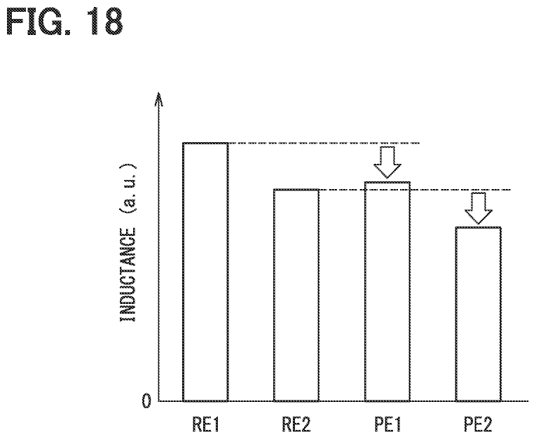

FIG. 18 shows the results of the electromagnetic field simulation. The vertical axis represents inductance in arbitrary units (a.u.). RE1 and RE2 indicate the results of the reference examples, and PE1 and PE2 indicate the results of the configuration examples (the present examples) equivalent to the present embodiment. Unlike the present examples, the reference examples include a conductive spacer. In the present example, since the conductive spacer is not provided, the distance between the facing surfaces of the front surface metal bodies is reduced by the thickness of the conductive spacer. In RE1 and PE1, the insulating base materials 51 and 61 were made of nitride-based ceramic. In RE2 and PE2, the insulating base materials 51 and 61 were made of resin.

As shown in FIG. 18, according to the present examples (PE1, PE2), it is apparent that the inductance can be reduced by about 20%, as compared with the reference examples (RE1, RE2), in any cases of using either ceramic or resin.

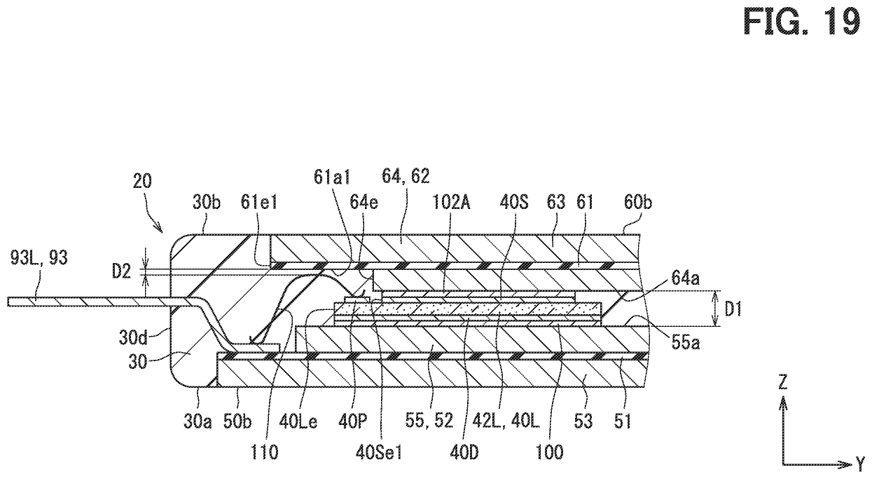

Even if the bonding wire 110 is in contact with the exposed portions 61a1 and 61a2 of the insulating base material 61 in the second connection step described above, the bonding wire 110 may be slightly separated from the exposed portion 61a1 or 61a2 in a step subsequent to the second connection step, for example, a molding step. Therefore, as shown in FIG. 19, the semiconductor device 20 may have a slight gap having a distance D2 of 0.1 mm or less between the bonding wire 110 and the exposed portion 61a1 or 61a2 of the insulating base material 61. Since the distance D1 between the facing surfaces is determined in the second connection step, the same effect as that of the configuration shown in FIG. 16 can be obtained.

### Modification

The above-described manufacturing method may be applied to a configuration including the conductive spacer 70. That is, in the configuration including the conductive spacer 70, the bonding wire 110 may be brought into contact with the exposed portion 61a1 or 61a2 of the insulating base material 61, or may have a slight gap of 0.1 mm or less. The thickness of the conductive spacer 70 can be reduced.

The configuration described in the present embodiment can be combined with any configuration of the first embodiment and the modification.

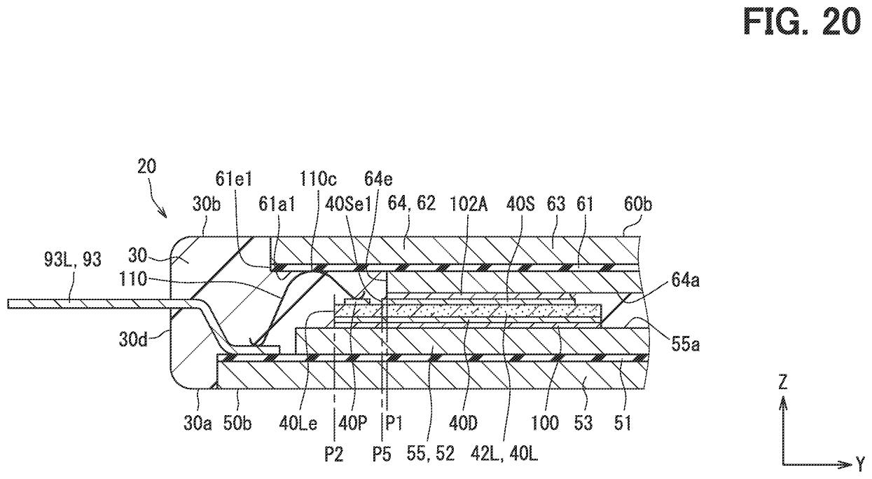

The example in which the end portions 64e and 65e of the front surface metal body 62 are located between the end portions 40Se1 and 40Se2 of the source electrode 40S and the end portions 40Le and 40He of the semiconductor element 40 has been described, but the present disclosure is not limited thereto. For example, as shown in FIG. 20, the position P1 of the end portion 64e of the N wiring 64 may be located more to inside than the position P5 of the end portion 40Se1 of the source electrode 40S as the bonding target. The end portion 40Se1 is located between the end portions 40Le and 64e in the Y direction. As described above, according to the present embodiment, when the source electrode 40S (second main electrode) and the substrate 60 (second wiring member) are electrically connected, the bonding wire 110 is pressed by the insulating base material 61 of the substrate 50. As a result, the distance D1 between the opposing surfaces can be shortened. Therefore, even if the end portions 64e and 65e of the front surface metal body 62 do not have the above-described positional relationship, the inductance and the thermal resistance can be effectively reduced.

### Third Embodiment

The present embodiment is a modification of the preceding embodiments as a basic configuration and may incorporate description of the preceding embodiments. In the preceding embodiments, the semiconductor device 20 includes two semiconductor elements 40H and two semiconductor elements 40L, and in which the semiconductor elements 40H are arranged in the X direction, the semiconductor elements 40L are arranged in the X direction, and the semiconductor element 40H and the semiconductor element 40L are arranged in the Y direction. In addition, the P terminal 91P, the N terminal 91N, and the signal terminal 93H protrude from one of the side surfaces of the sealing body 30 in the Y direction, and the output terminal 92 and the signal terminal 93L protrude from the opposite side surface.

However, the number and arrangement of the semiconductor elements 40, the arrangement of the external connection terminals 90, and the like are not limited to the example described above. For example, each arm may be constituted by one semiconductor element 40 instead of the plurality of semiconductor elements 40. Instead of the configuration in which the signal terminals 93H and 93L are arranged so as to interpose the semiconductor element 40 therebetween, the signal terminal 93H and the signal terminal 93L may be arranged side by side.

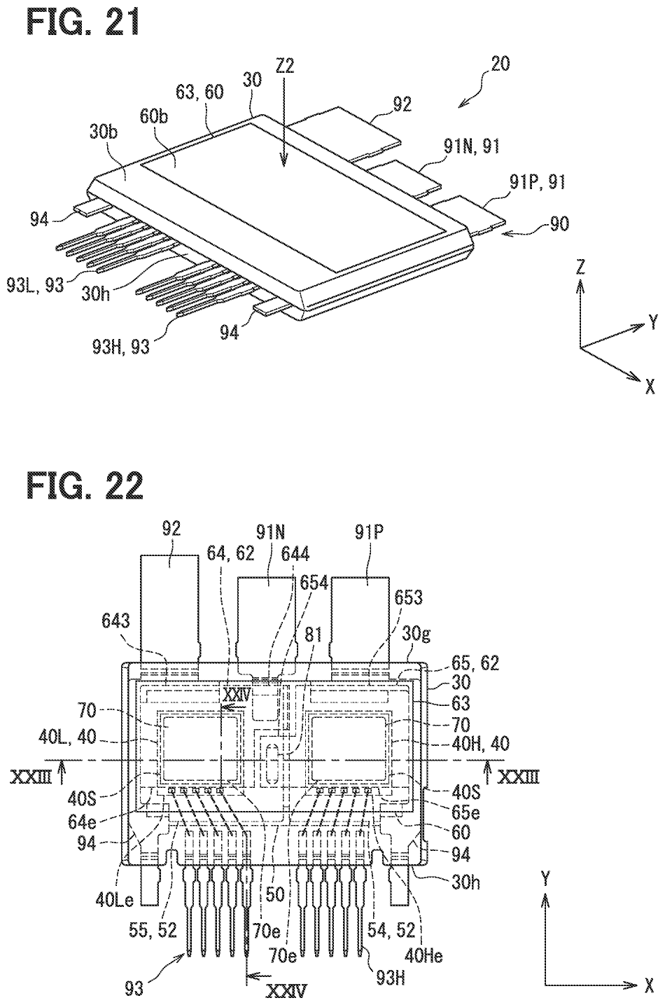

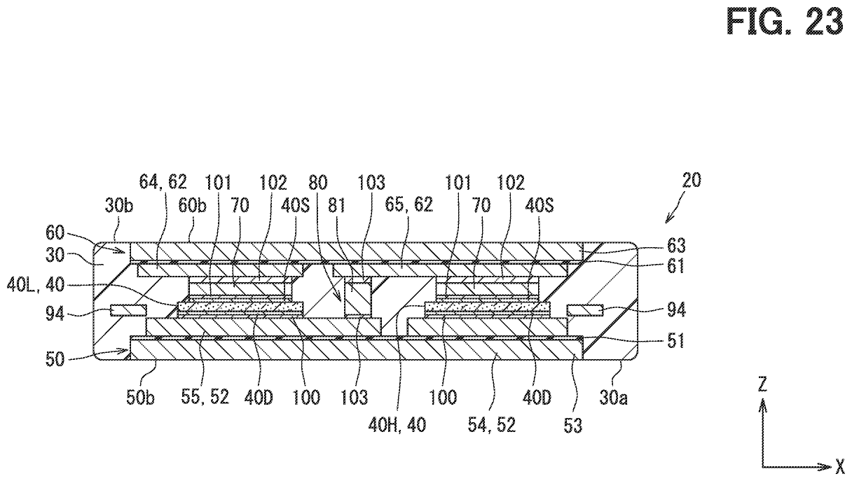

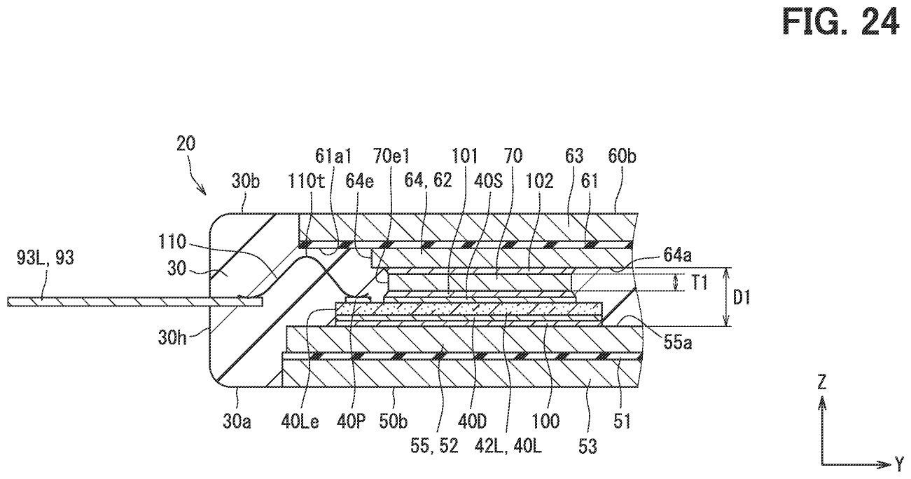

FIGS. 21 to 24 show a semiconductor device 20 of the present embodiment. FIG. 21 is a perspective view of the semiconductor device 20. FIG. 22 is a plan view of FIG. 21 viewed along the direction Z2. FIG. 22 is a transparent view showing the internal structure. FIG. 23 is a cross-sectional view taken along a line XXIII-XXIII in FIG. 22. FIG. 24 is a cross-sectional view taken along a line XXIV-XXIV in FIG. 22.

The semiconductor device 20 of the present embodiment constitutes one upper-lower arm circuit 9, that is, the upper-lower arm circuit 9 for one phase, as in the preceding embodiment. The semiconductor device 20 includes elements similar to those of the configuration described in the preceding embodiment (see FIGS. 2 to 11). The semiconductor device 20 includes a sealing body 30, a semiconductor element 40, substrates 50 and 60, a conductive spacer 70, an arm connection portion 80, and an external connection terminal 90. Hereinafter, portions different from the configurations described in the preceding embodiment will be mainly described.

The sealing body 30 seals a part of other elements constituting the semiconductor device 20 as in the preceding embodiment. As shown in FIG. 21, the sealing body 30 has a substantially rectangular shape as the planar shape. The sealing body 30 has a first surface 30a and a second surface 30b in the Z direction. Side surfaces connecting the first surface 30a and the second surface 30b include two side surfaces 30g and 30h from which the external connection terminals 90 protrude. The side surface 30h is a surface opposite to the side surface 30g in the Y direction.

The semiconductor element 40 includes one semiconductor element 40H constituting the upper arm 9H and one semiconductor element 40L constituting the lower arm 9L. The semiconductor device 20 includes two semiconductor elements 40. The configurations of the semiconductor elements 40H and 40L are common to each other. As shown in FIG. 22, the semiconductor elements 40H and 40L are arranged in the X direction. The semiconductor elements 40 are disposed at substantially the same position in the Z direction. The drain electrode 40D of each of the semiconductor elements 40 faces the substrate 50. The source electrode 40S of each of the semiconductor elements 40 faces the substrate 60.

The substrates 50 and 60 are disposed so as to interpose the plurality of semiconductor elements 40 in the Z direction. The substrates 50 and 60 are disposed such that at least portions thereof face each other in the Z direction. The substrates 50 and 60 encompass all of the plurality of semiconductor elements 40 (40H and 40L) in the plan view.

Similar to the preceding embodiment, the substrate 50 includes an insulating base material 51, a front surface metal body 52, and a back surface metal body 53. The substrate 60 includes an insulating base material 61, a front surface metal body 62, and a back surface metal body 63. The front surface metal body 52 includes a P wiring 54 and a relay wiring 55. The P wiring 54 and the relay wiring 55 are electrically separated by a predetermined interval (gap).

The P wiring 54 is connected to the P terminal 91P and the drain electrode 40D of the semiconductor element 40H. The P wiring 54 electrically connects the P terminal 91P and the drain electrode 40D of the semiconductor element 40H. The P wiring 54 has a substantially rectangular planar shape defining the longitudinal direction in the Y direction. The relay wiring 55 is connected to the drain electrode 40D of the semiconductor element 40L, the arm connection portion 80, and the output terminal 92. The relay wiring 55 has a substantially rectangular planar shape.

The P wiring 54 and the relay wiring 55 are arranged side by side in the X direction. The semiconductor element 40L is mounted on one end side of the relay wiring 55 in the X direction, specifically, on a side far from the P wiring 54. The joint portion 81 constituting the arm connection portion 80 is mounted on the other end side of the relay wiring 55 in the X direction, specifically, on the side close to the P wiring 54. The P terminal 91P is connected to the vicinity of one end of the P wiring 54 in the Y direction. The output terminal 92 is connected to the vicinity of one end of the relay wiring 55 in the Y direction. The P terminal 91P and the output terminal 92 are disposed on the same side of the semiconductor element 40 in the Y direction.

The front surface metal body 62 includes an N wiring 64 and a relay wiring 65. The N wiring 64 and the relay wiring 65 are electrically separated by a predetermined interval (gap). The N wiring 64 is connected to the N terminal 91N and the source electrode 40S of the semiconductor element 40L. The relay wiring 65 is connected to the source electrode 40S of the semiconductor element 40H and the arm connection portion 80.

The N wiring 64 has a base portion 643 and an extension portion 644. The N wiring 64 has substantially an L-shape as the planar shape. The base portion 643 has substantially a rectangular shape as the planar shape. The base portion 643 encompasses a part of the semiconductor element 40L in the plan view. The base portion 643 encompasses the source electrode 40S of the semiconductor element 40L. The extension portion 644 connects to one side of the base portion 643 having substantially the rectangular shape in the plan view. The extension portion 644 extends from a side of the base portion 643 facing the relay wiring 65 toward the base portion 653 in the X direction.

In the N wiring 64 (base portion 643), an end portion 64e which is a side on the signal terminal 93L side is located between the end portion 40Le of the semiconductor element 40L and the end portion 70e of the conductive spacer 70 as the bonding target in the Y direction.

The relay wiring 65 includes a base portion 653 and an extension portion 654. The relay wiring 65 has substantially an L-shape as the planar shape. The base portion 653 has substantially a rectangular shape as the planar shape. The base portion 653 encompasses a part of the semiconductor element 40H in the plan view. The base portion 653 encompasses the source electrode 40S of the semiconductor element 40L. The extension portion 654 connects to one side of the base portion 653 having substantially the rectangular shape as the planar shape The extension portion 654 extends from a side of the base portion 653 facing the N wiring 64 toward the base portion 643 in the X direction. At least a part of the extension portion 654 overlaps the relay wiring 55 in the plan view.

In the relay wiring 65, an end portion 65e, which is a side on the signal terminal 93H side, is located between the end portion 40He of the semiconductor element 40H and the end portion 70e of the conductive spacer 70 as the bonding target in the Y direction.

The N wiring 64 and the relay wiring 65 are arranged side by side in the X direction. The base portion 643 and the base portion 653 are arranged in the X direction. The source electrode 40S of the semiconductor element 40L is electrically connected to the base portion 643. The source electrode 40S of the semiconductor element 40H is electrically connected to the base portion 653. The extension portion 644 and the extension portion 654 are arranged in the Y direction. The N terminal 91N is connected to the extension portion 644. The joint portion 81 is connected to the extension portion 654.

The conductive spacer 70 is interposed between the source electrode 40S of the semiconductor element 40 and the substrate 60. The conductive spacers 70 are individually connected to the source electrodes 40S of the semiconductor elements 40.

The arm connection portion 80 electrically connects the relay wiring 55 and the relay wiring 65. The arm connection portion 80 is provided between the semiconductor element 40H and the semiconductor element 40L in the X direction. The arm connection portion 80 is provided in an overlapping region between the relay wiring 55 and the relay wiring 65 (extension portion 654) in the plan view. The arm connection portion 80 of the present embodiment is configured to include the joint portion 81 and the bonding material 103 as in the preceding embodiment. The joint portion 81 is a metal columnar body. In the Z direction, the bonding material 103 is interposed between one of the end portions of the joint portion 81 and the relay wiring 55, and the bonding material 103 is interposed between the other one of the end portions of the joint portion 81 and the relay wiring 65. Alternatively, the joint portion 81 may integrally connect to at least one of the front surface metal bodies 52 and 62. The arm connection portion 80 may not include the joint portion 81.

The external connection terminal 90 includes a power supply terminal 91, an output terminal 92, and a signal terminal 93. The power supply terminal 91 includes a P terminal 91P and an N terminal 91N. Hereinafter, the P terminal 91P, the N terminal 91N, and the output terminal 92 may be referred to as main terminals 91P, 91N, and 92. The signal terminal 93 includes a signal terminal 93H on the upper arm 9H side and a signal terminal 93L on the lower arm 9L side.

The P terminal 91P is connected to the vicinity of one end of the P wiring 54 in the Y direction. The P terminal 91P extends outward in the Y direction from the connection portion with the P wiring 54. A portion of the P terminal 91P is covered with the sealing body 30, and the remaining portion protrudes from the sealing body 30. The P terminal 91P protrudes to the outside of the sealing body 30 from the vicinity of the center of the side surface 30g in the Z direction.

The N terminal 91N is connected to the vicinity of one end of the N wiring 64 in the Y direction. The N terminal 91N extends outward in the Y direction from the connection portion with the N wire 64. A part of the N terminal 91N is covered with the sealing body 30, and the remaining part protrudes from the sealing body 30. The N terminal 91N protrudes to the outside of the sealing body 30 from the vicinity of the center of the side surface 30g in the Z direction.

The output terminal 92 is connected to the vicinity of one end of the relay wiring 55 in the Y direction. The output terminal 92 extends outward in the Y direction from the connection portion with the relay wiring 55. A portion of the output terminal 92 is covered with the sealing body 30, and the remaining portion protrudes from the sealing body 30. The output terminal 92 protrudes to the outside of the sealing body 30 from the vicinity of the center of the side surface 30g in the Z direction.

The three main terminals 91P, 91N, and 92 are arranged side by side in the X direction. The main terminals 91P, 91N, and 92 are arranged in the order of the P terminal 91P, the N terminal 91N, and the output terminal 92 in the X direction. Side surfaces of the P terminal 91P and the N terminal 91N, which are the power supply terminals 91, face each other at a part including portions protruding from the sealing body 30.

The signal terminal 93 is electrically connected to the pad 40P of the corresponding semiconductor element 40 via the bonding wire 110. The signal terminal 93H is connected to the pad 40P of the semiconductor element 40H via a bonding wire 110. The signal terminal 93L is connected to the pad 40P of the semiconductor element 40L via a bonding wire 110. The signal terminal 93 extends outward in the Y direction and protrudes to the outside of the sealing body 30 from the vicinity of the center of the side surface 30h in the Z direction. The signal terminal 93 is extended on the side opposite to the main terminals 91P, 91N, and 92 in the Y direction. The semiconductor element 40 is disposed between the main terminals 91P, 91N, and 92 and the signal terminal 93 in the Y direction.

The semiconductor device 20 includes two guide frames 94. One of the guide frames 94 connects to the P terminal 91P. The other guide frame 94 connects to the output terminal 92. These guide frames 94 are portions that connect an outer peripheral frame holding the signal terminals 93 and the main terminals 91P and 92 in a state before unnecessary portions of the lead frame are removed. A part of the guide frame 94 connecting to the P terminal 91P is connected to the P wiring 54. A part of the guide frame 94 connecting to the output terminal 92 is connected to the relay wiring 55. The guide frame 94 can have the same connection structure (bonding structure) as the main terminals 91P, 91N, and 92.

As described above, in the semiconductor device 20 of the present embodiment, the plurality of semiconductor elements 40 constituting the upper-lower arm circuit 9 for one phase are sealed by the sealing body 30. The sealing body 30 integrally seals the plurality of semiconductor elements 40, a part of the substrate 50, a part of the substrate 60, the plurality of conductive spacers 70, the arm connection portion 80, and a part of each of the external connection terminals 90. The sealing body 30 seals the insulating base materials 51 and 61 and the front surface metal bodies 52 and 62 of the substrates 50 and 60.

The semiconductor element 40 is disposed between the substrates 50 and 60 in the Z direction. The semiconductor element 40 is interposed between the substrates 50 and 60 arranged to face each other. Accordingly, the heat of the semiconductor element 40 can be dissipated to both sides in the Z direction. The semiconductor device 20 has a double-sided heat dissipation structure. The back surface 50b of the substrate 50 is substantially flush with the first surface 30a of the sealing body 30. The back surface 60b of the substrate 60 is substantially flush with the second surface 30b of the sealing body 30. Since the back surfaces 50b and 60b are exposed surfaces, heat dissipation can be improved.

### Summary of Third Embodiment

The positions of the end portions 64e and 65e of the front surface metal body 62 in the present embodiment are the same as those in the preceding embodiments. Therefore, the same effects as those of the configurations described in the preceding embodiments can be achieved. That is, it is possible to reduce the thermal resistance while reducing the inductance.

The configuration described in the present embodiment can be combined with any configuration of the first embodiment, the second embodiment, and the modification. For example, in the present embodiment, notches 620 and 621 may be provided in the front surface metal body 62, as shown in FIG. 14, The pads 40P may be provided so as to be biased to one of the corners of the rectangle, and the notches 622 and 623 may be provided in the front surface metal body 62, as shown in FIG. 15. The bonding wires 110 may be brought into contact with the exposed portions 61a1 and 61a2 of the front surface metal body 62, as shown in FIG. 16. The conductive spacer 70 may be omitted.

### Other Embodiments

The present disclosure in the specification, the drawings and the like is not limited to the embodiments exemplified hereinabove. The disclosure encompasses the illustrated embodiments and modifications by those skilled in the art based thereon. For example, the present disclosure is not limited to the combinations of components and/or elements shown in the embodiments. The present disclosure may be implemented in various combinations thereof. The present disclosure may have additional parts that may be added to the embodiments. The present disclosure encompasses modifications in which components and/or elements are omitted from the embodiments. The present disclosure encompasses the replacement or combination of components and/or elements between one embodiment and another. The technical scopes disclosed in the present disclosure are not limited to the description of the embodiments. The several technical scopes disclosed are indicated by the description of the claims, and should be further understood to include meanings equivalent to the description of the claims and all modifications within the scope.

The disclosure in the specification, drawings and the like is not limited by the description of the claims. The disclosure in the specification, the drawings, and the like encompasses the technical ideas described in the claims, and further extends to a wider variety of technical ideas than those in the claims. Hence, various technical ideas can be extracted from the disclosure of the specification, the drawings, and the like without being bound by the description of the claims.

When an element or layer is referred to as being “on,” “coupled,” “connected,” or “combined,” it may be directly on, coupled to, connected to, or combined with the other element or layer, or further, intervening elements or layers may be present. In contrast, when an element is described as “directly disposed on,” “directly coupled to,” “directly connected to”, or “directly combined with” another element or another layer, there are no intervening elements or layers present. Other terms used to describe the relationships between elements (for example, “between” vs. “directly between”, and “adjacent” vs. “directly adjacent”) should be interpreted similarly. As used herein, the term “and/or” includes any combination and all combinations relating to one or more of the related listed items. For example, the term A and/or B includes only A, only B, or both A and B.

Spatially relative terms such as “inner,” “outer,” “back,” “below,” “low,” “above,” and “high” are utilized herein to facilitate description of one element or feature's relationship to another element (s) or feature (s) as illustrated. Spatial relative terms can be intended to include different orientations of a device in use or operation, in addition to the orientations illustrated in the drawings. For example, when a device in a drawing is turned over, elements described as “below” or “directly below” other elements or features are oriented “above” the other elements or features. Therefore, the term “below” can include both above and below. The device may be oriented in the other direction (rotated 90 degrees or in any other direction) and the spatially relative terms used herein are interpreted accordingly.

The vehicle drive system 1 is not limited to the configurations of the embodiments described above. Although the example in which the vehicle drive system 1 includes one motor generator 3 has been described, the present disclosure is not limited thereto. A plurality of motor generators may be provided. Although the example in which the electric power conversion device 4 includes the inverter 6 as a power conversion circuit has been described, the present disclosure is not limited thereto. For example, the electric power conversion device 4 may include a plurality of inverters. The electric power conversion device 4 may include at least one inverter and a converter. The electric power conversion device 4 may include only the converter.

The example in which the semiconductor element 40 includes the MOSFET 11 as a switching element has been described, but the present disclosure is not limited thereto. For example, an IGBT may be employed. IGBT is an abbreviation of Insulated Gate Bipolar Transistor.

Although the substrate 50 is exemplified as the wiring member connected to the drain electrode 40D, the wiring member is not limited thereto. In the configuration in which the wiring member is not limited to the substrate 50, a metal plate (lead frame) may be adopted instead of the substrate 50. In the case of the wiring member made of the metal plate, a first metal plate to which the drain electrode 40D of the semiconductor element 40H is connected and a second metal plate to which the drain electrode 40D of the semiconductor element 40L is connected are disposed on the drain electrode 40D side.

The example in which one semiconductor device 20 constitutes the upper-lower arm circuit 9 (two arms) for one phase has been described, but the present disclosure is not limited thereto. For example, the present disclosure can be applied to a semiconductor device in which one semiconductor device 20 constitutes one arm. The number of arms configured by one semiconductor device 20 is not particularly limited.

What is claimed is:

1. A semiconductor device comprising:
a semiconductor element having a first surface and a second surface opposite to the first surface in a thickness direction, the semiconductor element including a first main electrode disposed on the first surface, a second main electrode disposed on the second surface, and a signal pad disposed at a position different from the second main electrode on the second surface;
a first wiring member electrically connected to the first main electrode;
a second wiring member electrically connected to the second main electrode;
a signal terminal; and
a bonding wire electrically connecting the signal pad and the signal terminal, wherein
the second wiring member is a substrate that includes an insulating base material, a front surface metal body, and a back surface metal body, the front surface metal body is disposed on a front surface of the insulating base material facing the semiconductor element and electrically connected to the second main electrode, and the back surface metal body is disposed on a back surface of the insulating base material opposite to the front surface,
an end portion of the front surface metal body is located between an end portion of a bonding target to which the front surface metal body is bonded and an end portion of the semiconductor element in an arrangement direction in which the semiconductor element and the signal terminal are arranged,
the insulating base material has an exposed portion exposed from the front surface metal body,
a top portion of the bonding wire faces the exposed portion of the insulating base material in the thickness direction, and
the bonding wire is in contact with the exposed portion of the insulating base material.

2. The semiconductor device according to claim 1, wherein
the end portion of the front surface metal body is located between an end portion of the signal pad adjacent to the second main electrode and the end portion of the semiconductor element in the arrangement direction.

3. The semiconductor device according to claim 1, wherein
the front surface metal body is thicker than the back surface metal body.

4. The semiconductor device according to claim 1, further comprising:
a conductive spacer interposed between the second main electrode and the front surface metal body, and
the bonding target is the conductive spacer.

5. The semiconductor device according to claim 1, wherein
the bonding target is the second main electrode.

6. A method for manufacturing a semiconductor device, the method comprising:
electrically connecting a first main electrode disposed on a first surface of a semiconductor element and a first wiring member;
connecting a signal pad disposed on a second surface of the semiconductor element opposite to the first surface and a signal terminal through a bonding wire; and
after the connecting of the signal pad and the signal terminal through the bonding wire, electrically connecting a second main electrode disposed on the second surface of the semiconductor element at a position different from the signal pad and a second wiring member, wherein
the electrically connecting of the second main electrode and the second wiring member includes using, as the second wiring member, a substrate that includes an insulating base material, a front surface metal body disposed on a front surface of the insulating base material adjacent to the semiconductor element and electrically connected to the second main electrode, and a back surface metal body disposed on a back surface of the insulating base material opposite to the front surface, and in which the front surface metal body is patterned such that an end portion of the front surface metal body is located between an end portion of a bonding target to which the front surface metal body is bonded and an end portion of the semiconductor element in an arrangement direction of the semiconductor element and the signal terminal; and
the second main electrode and the second wiring member are electrically connected in a state where an exposed portion of the insulating base material exposed from the front surface metal body is in contact with the bonding wire.
